(19) United States
(12) Patent Application Publication
(10) Pub. No.: US 2025/0391801 A1
(43) Pub. Date: Dec. 25, 2025

(54) SEMICONDUCTOR PACKAGE AND METHODS OF MANUFACTURING THE SAME

(71) Applicant: Taiwan Semiconductor Manufacturing Company, Ltd., Hsinchu (TW)

(72) Inventors: Kuan-Yu Huang, Taipei (TW); Sung-Hui Huang, Yilan County (TW); Hsien-Pin Hu, Hsinchu County (TW)

(73) Assignee: Taiwan Semiconductor Manufacturing Company, Ltd., Hsinchu (TW)

(21) Appl. No.: 18/748,095

(22) Filed: Jun. 20, 2024

(51) Int. Cl. H01L 23/00; H01L 21/56; H01L 23/31; H01L 25/065

(52) U.S. Cl. CPC H01L 24/32; H01L 21/56; H01L 23/3157; H01L 24/83; H01L 24/16; H01L 24/73; H01L 24/96; H01L 24/97; H01L 25/0655; H01L 2224/16145; H01L 2224/16227; H01L 2224/32145; H01L 2224/32225; H01L 2224/73204; H01L 2224/83047; H01L 2224/83947; H01L 2224/96; H01L 2224/97; H01L 2924/1815

(57) ABSTRACT

A semiconductor package includes an interconnect substrate, a semiconductor die, and an underfill. The semiconductor die is disposed over the interconnect substrate and has a first top surface extends along a first direction. The underfill includes a body portion and an extending portion. The body portion is disposed between the interconnect substrate and the semiconductor die. The extending portion connects to the body portion, where the extending portion is next to the semiconductor die and has a second top surface extends along the first direction.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1, FIG. 3, FIG. 5, FIG. 11, FIG. 17, FIG. 18, and FIG. 19 are schematic cross-sectional views of various stages in manufacturing a semiconductor package in accordance with some embodiments of the disclosure.

FIG. 2 and FIG. 20 are schematic plane views of various stages in manufacturing a semiconductor package in accordance with some embodiments of the disclosure.

FIG. 4 is a schematically enlarged, plane view showing cutting lines corresponding to a device region in manufacturing a semiconductor package in accordance with some embodiments of the disclosure.

FIG. 6 through FIG. 10 are schematic, cross-sectional and enlarged views respectively showing various embodiments of a semiconductor die and an underfill at a cutting region in a semiconductor package in accordance with the disclosure.

FIG. 12 through FIG. 16 are schematic, cross-sectional and enlarged views respectively showing various embodiments of a semiconductor die, an underfill and an insulating encapsulation at a cutting region in a semiconductor package in accordance with the disclosure.

FIG. 21 is a schematic cross-sectional view showing a semiconductor package in accordance with some alternative embodiments of the disclosure.

FIG. 22 is a schematic cross-sectional view of an application of a semiconductor package in accordance with some embodiments of the disclosure.

FIG. 23 is a schematic cross-sectional view showing a semiconductor package in accordance with some alternative embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for case of description to describe similar or different clement(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor package including a semiconductor die disposed on a circuit structure and an underfill filled between the semiconductor die and the circuit structure, where the underfill is trimmed to be free from an outermost side of the semiconductor die, in part or all. In some embodiments of the disclosure, the delamination between the trimmed underfill and underlying the circuit structure can be suppressed or eliminated. In addition, owing to trimming the underfill, the formation window of the underfill is enlarged. The manufacture of such semiconductor package is compatible to the current and/or advanced manufacturing processes.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

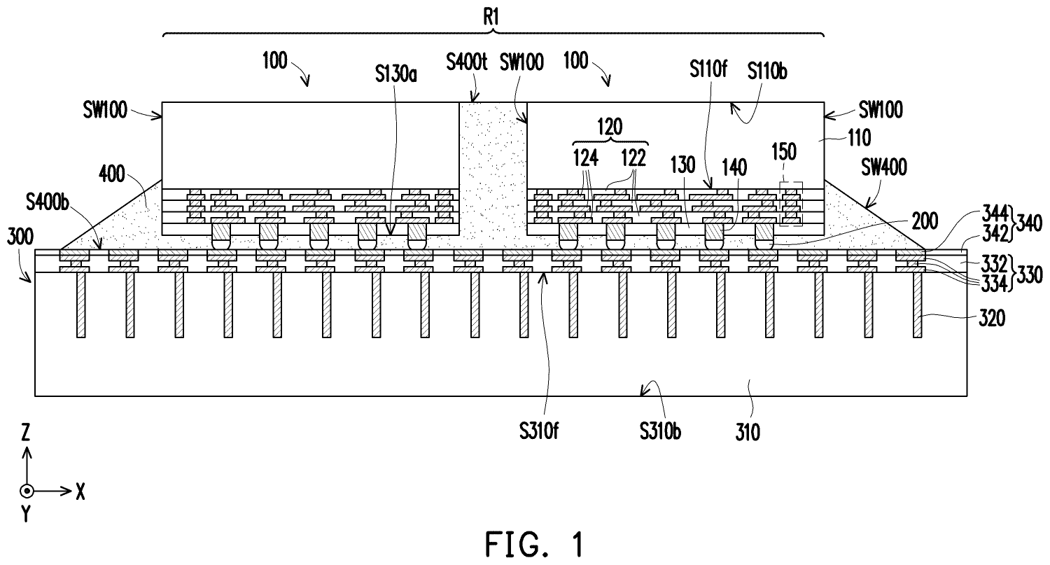

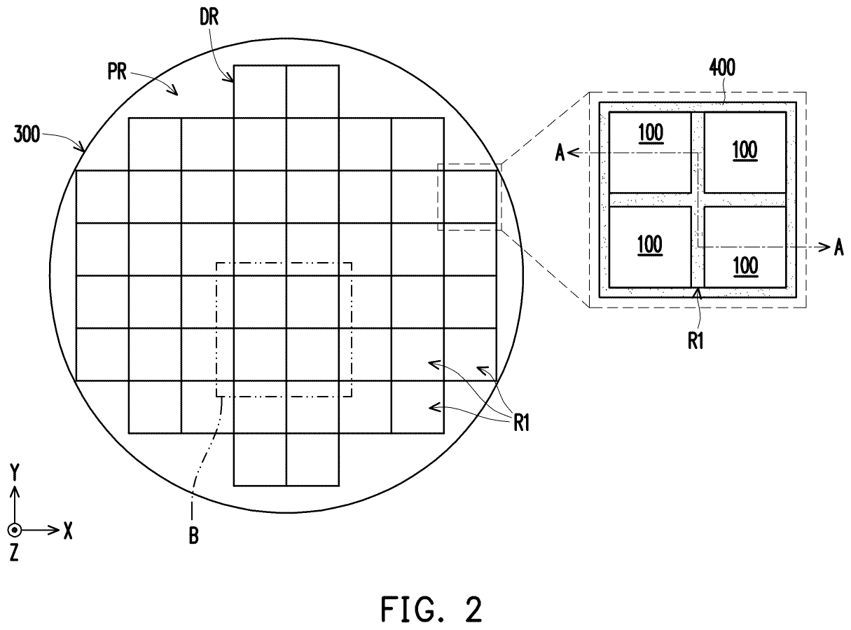

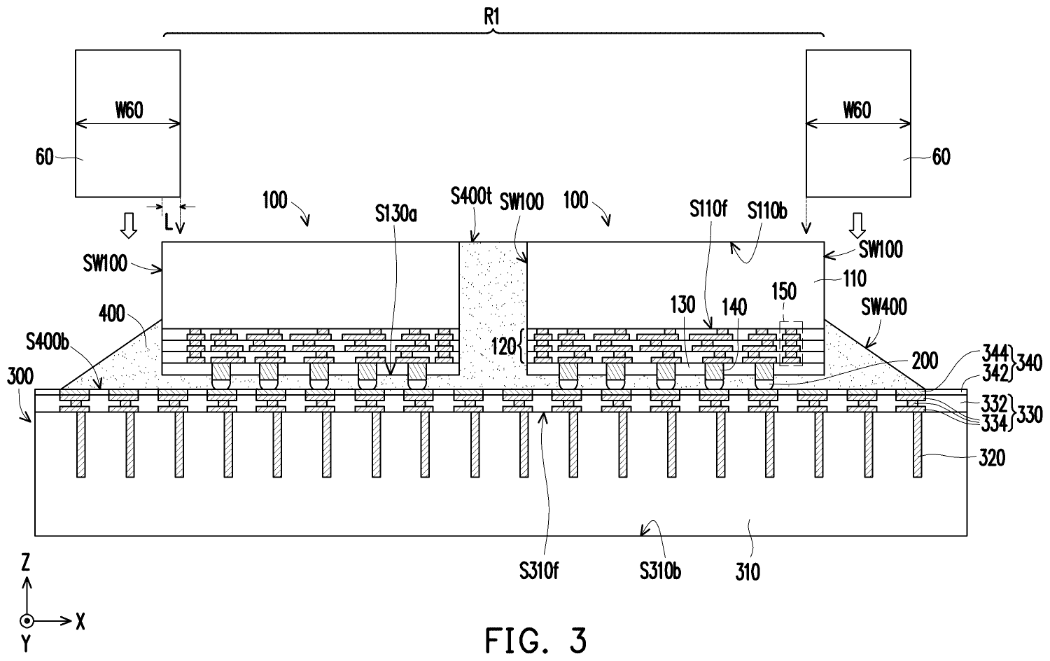

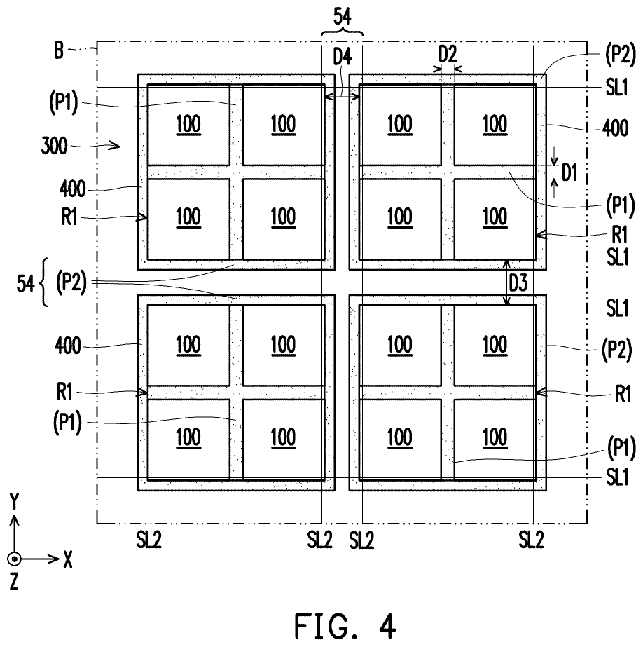

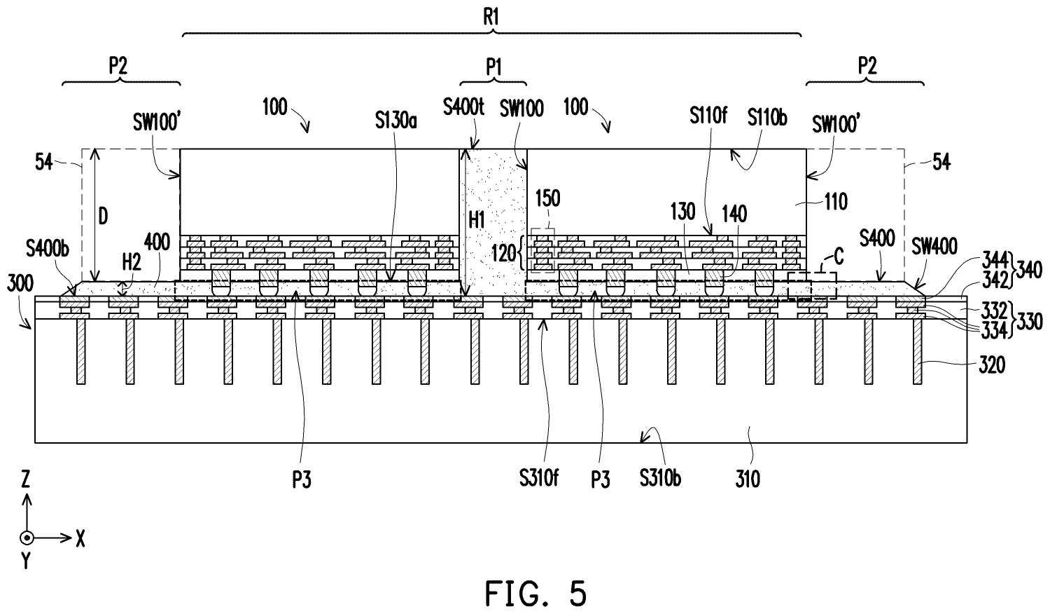

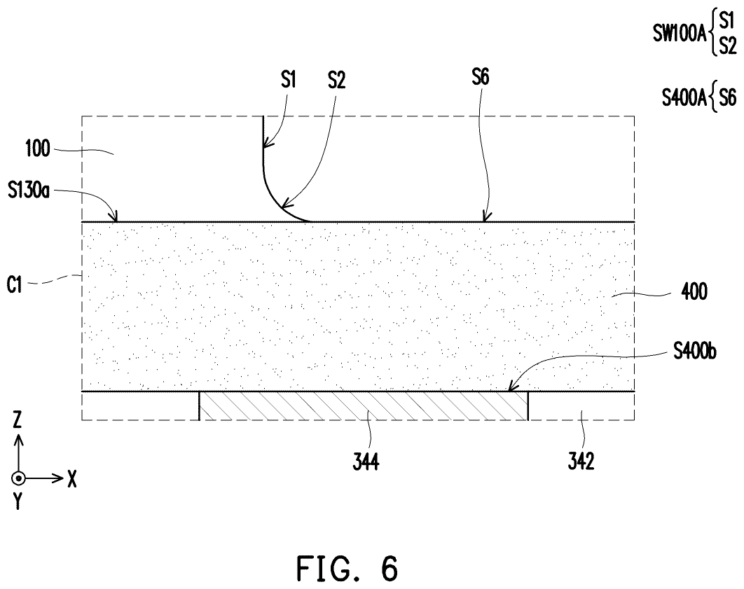

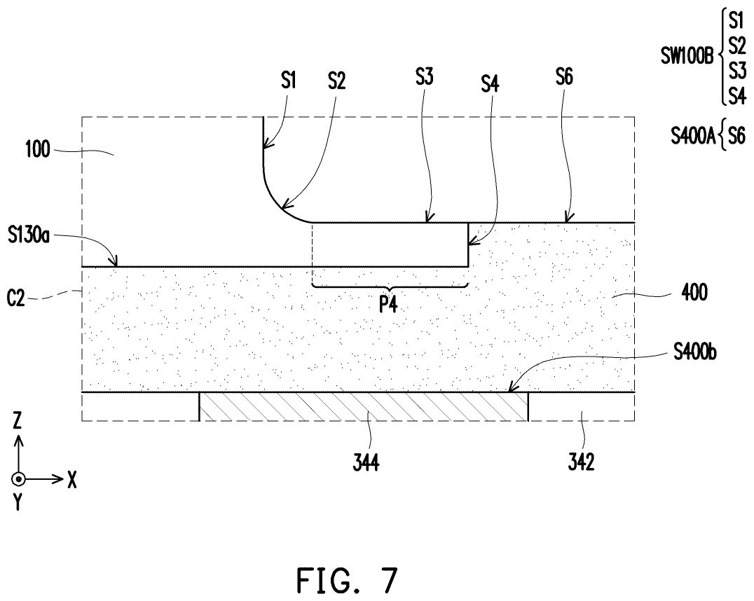

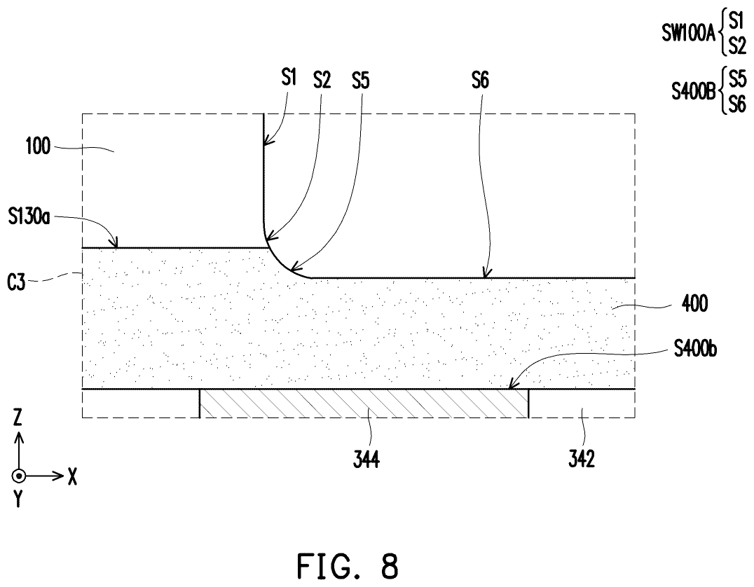

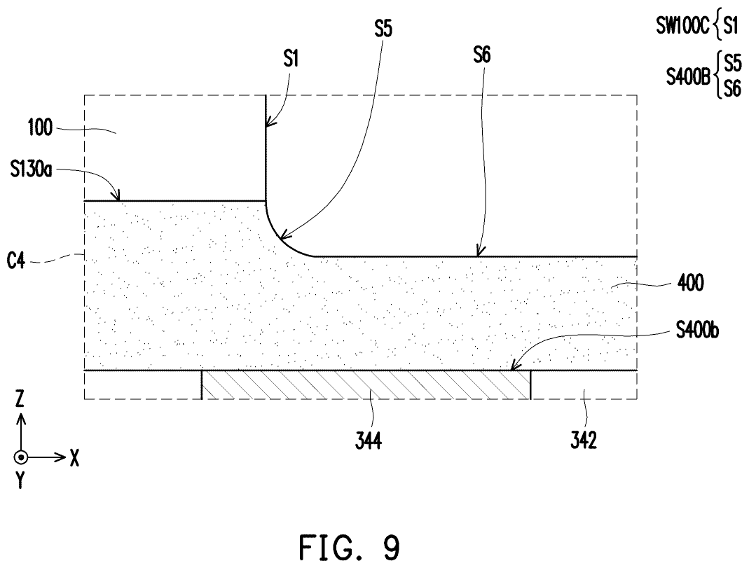

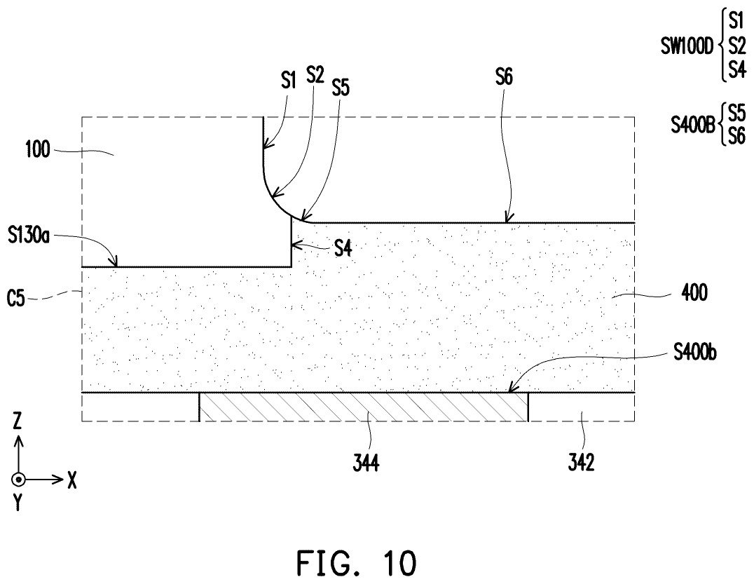

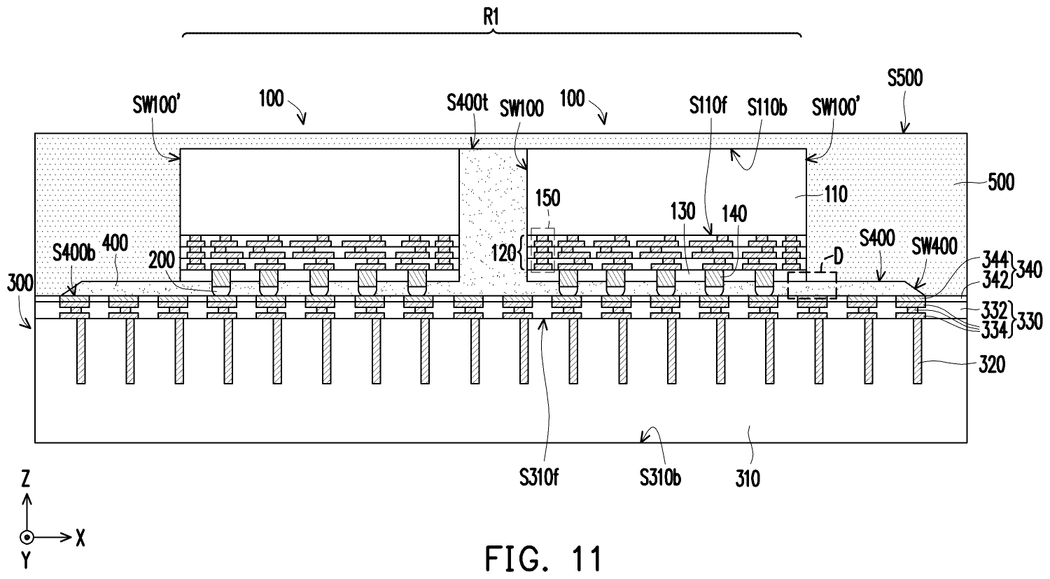

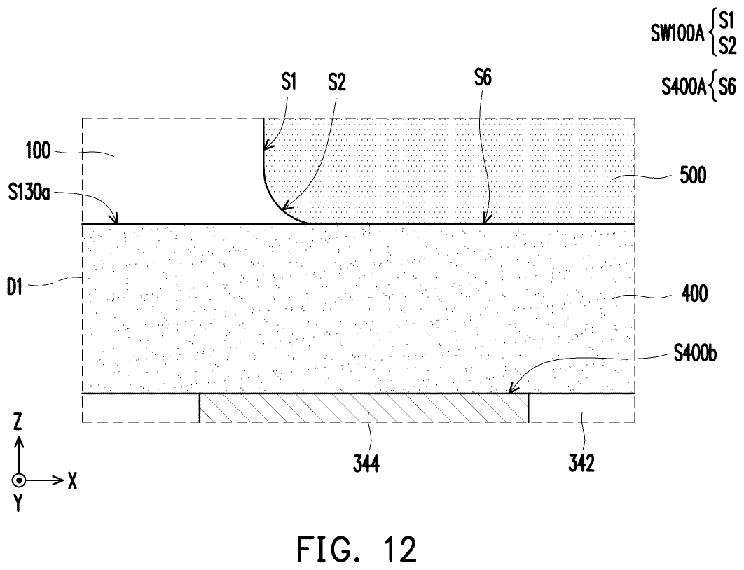

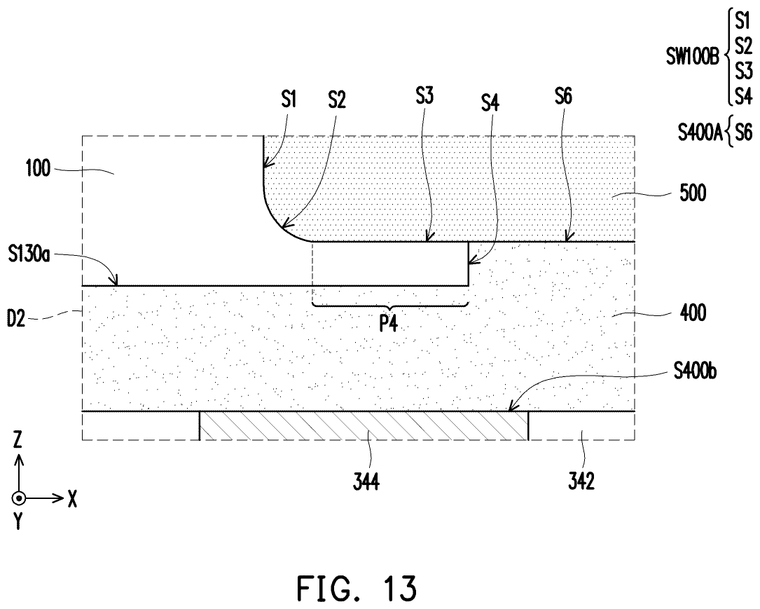

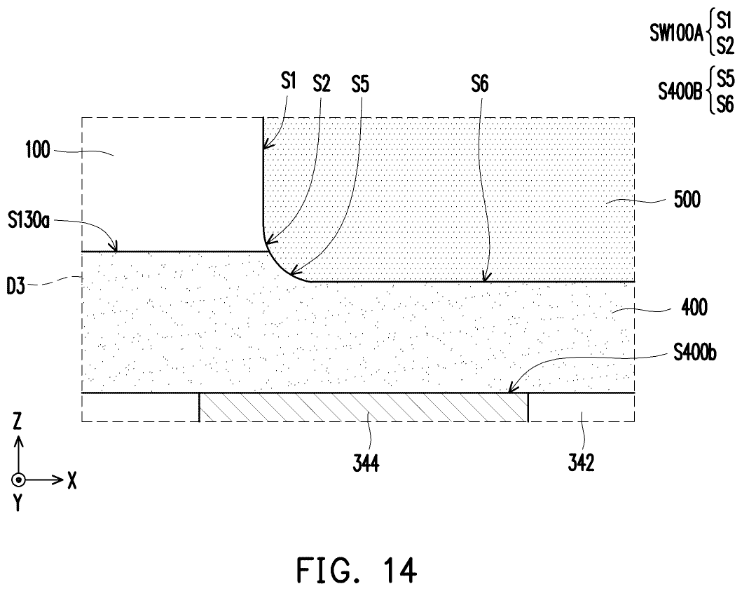

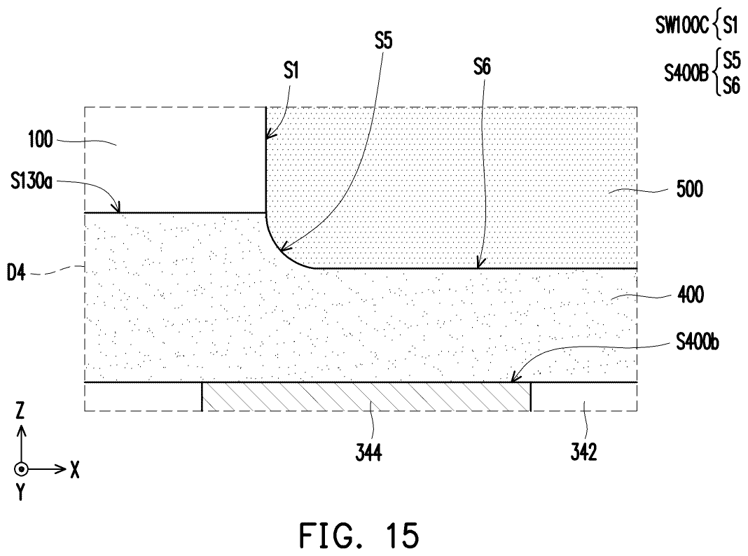

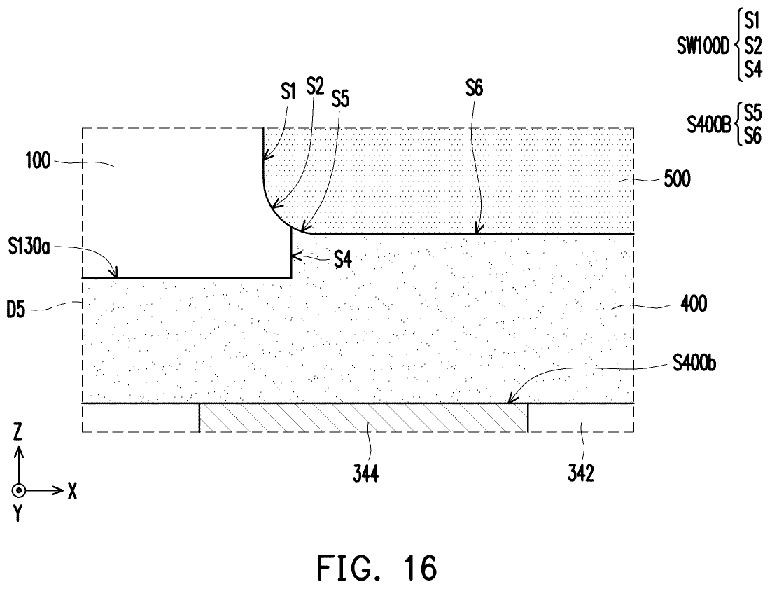

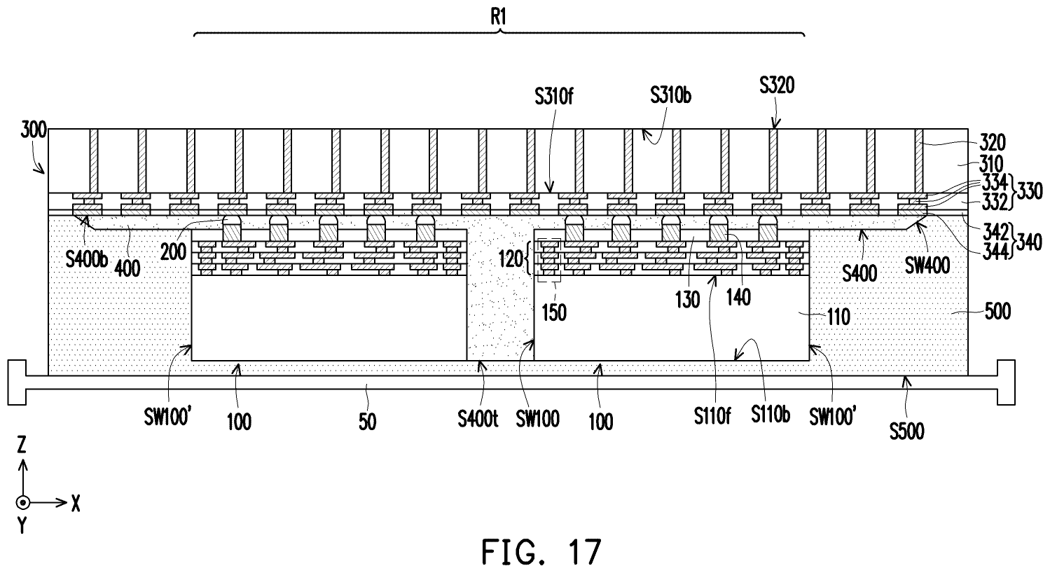

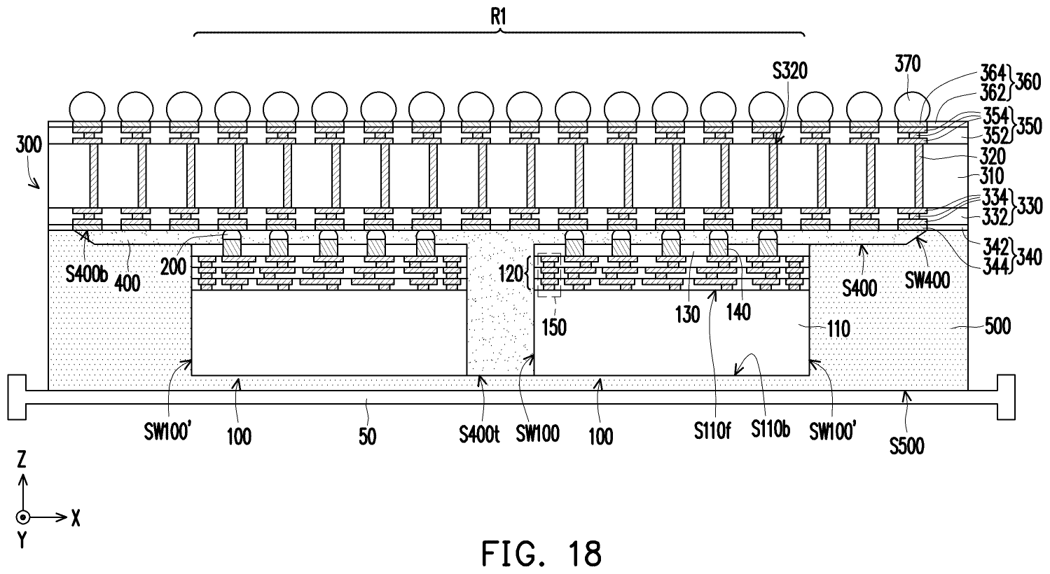

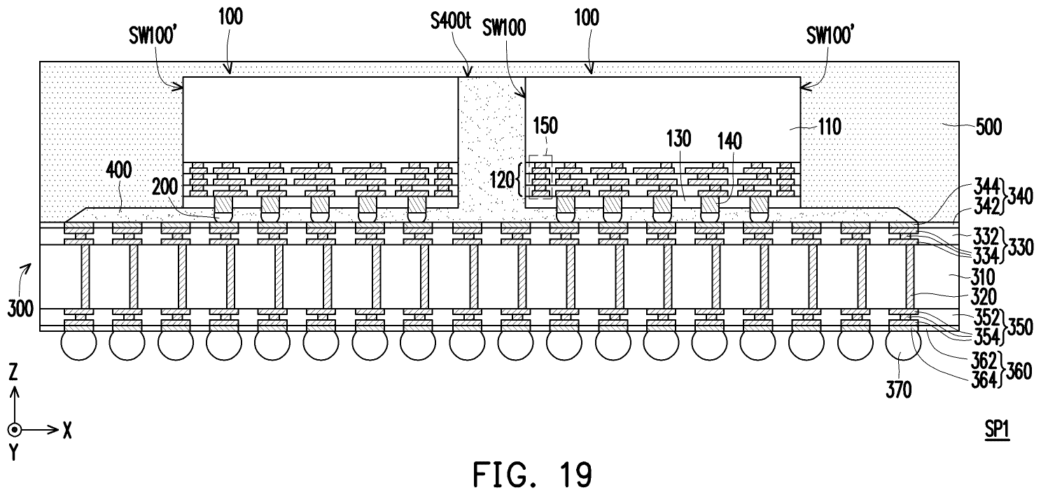

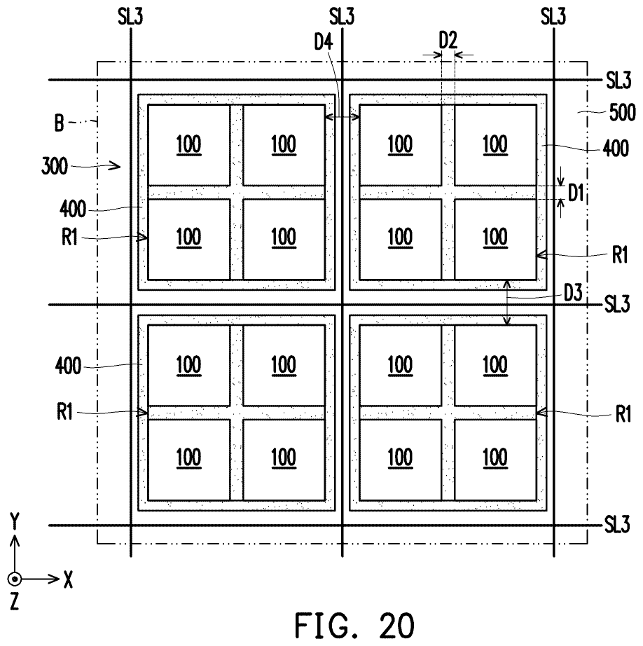

FIG. 1, FIG. 3, FIG. 5, FIG. 11, FIG. 17, FIG. 18, and FIG. 19 are schematic cross-sectional views of various stages in manufacturing a semiconductor package SP1 in accordance with some embodiments of the disclosure. FIG. 2 and FIG. 20 are schematic plane views of various stages in manufacturing the semiconductor package SP1, where the cross-sectional views of FIG. 1, FIG. 3, FIG. 5, FIG. 11, FIG. 17, FIG. 18, and FIG. 19 are taken along a line A-A depicted in the plane view of FIG. 2. FIG. 4 is a schematically enlarged, plane view showing cutting lines SL1, SL2 corresponding to a device region R1 in manufacturing the semiconductor package SP1, which are outlined by a dashed-box B depicted in FIG. 2. FIG. 6 through FIG. 10 are schematic, cross-sectional and enlarged views respectively showing various embodiments of the semiconductor die and an underfill at a cutting region in the semiconductor package of FIG. 5, which are outlined by a dashed-box C depicted in FIG. 5 (e.g., a dashed-box C1 in FIG. 6, a dashed-box C2 in FIG. 7, a dashed-box C3 in FIG. 8, a dashed-box C4 in FIG. 9, and/or a dashed-box C5 in FIG. 10). FIG. 12 through FIG. 16 are schematic, cross-sectional and enlarged views respectively showing various embodiments of a semiconductor die, an underfill and an insulating encapsulation at a cutting region in the semiconductor package of FIG. 11, which are outlined by a dashed-box D depicted in FIG. 11 (e.g., a dashed-box D1 in FIG. 12, a dashed-box D2 in FIG. 13, a dashed-box D3 in FIG. 14, a dashed-box D4 in FIG. 15, and/or a dashed-box D5 in FIG. 16).

Referring to FIG. 1 and FIG. 2, in some embodiments, a semiconductor element 300 is provided. In some embodiments, the semiconductor element 300 is an interposer. In some embodiments, the semiconductor element 300 is an integrated circuit device or an clement including a silicon substrate. In some embodiments, if considering a top or plane view (e.g., a X-Y plane) along a direction Z, the semiconductor element 300 is in a wafer or panel form. The semiconductor clement 300 may be in a form of wafer-size having a diameter of about 4 inches or more. The semiconductor element 300 may be in a form of wafer-size having a diameter of about 6 inches or more. The semiconductor element 300 may be in a form of wafer-size having a diameter of about 8 inches or more. Or alternatively, the semiconductor clement 300 may be in a form of wafer-size having a diameter of about 12 inches or more. In some embodiments, the semiconductor element 300 includes a device region DR and a peripheral region PR surrounding the device region DR, where the device region DR include a plurality of regions R1 arranged in a form of an array along a direction X and a direction Y, where each region R1 is a positioning (or pre-determined) location for placing semiconductor dies to be included in the semiconductor package SP1. The direction X, the direction Y and the direction Z may be different from each other. For example, the direction X is perpendicular to the direction Y, and the direction X and the direction Y are independently perpendicular to the direction Z, as shown in FIG. 1. In the disclosure, the direction Z may be referred to as a stacking or a vertical direction, the direction X and/or the direction may be referred to as a lateral or horizontal direction, and the X-Y plane defined by the direction X and the direction Y may be referred to as the plane view or top view.

In some embodiments, each of the regions R1 includes one or more semiconductor dies. For illustrated purposes, as shown in FIG. 2, each of the regions R1 may include four semiconductor dies 100, where the semiconductor dies 100 may be arranged into a 2×2 array. However, the disclosure is not limited thereto, the number of the semiconductor die for each region R1 may be one, two, three, fourth, or more, depending on the demand and the design requirement; as long as a shape/profile of each region R1 (in the X-Y plane) maintains a suitable shape (e.g., a rectangular shape or a square shape) which allows the regions R1 can be positioned into an arrangement for facilitating a sequent process.

In some embodiments, the semiconductor element 300 includes a substrate 310, a plurality of through vias 320, a redistribution circuit structure 330, a bonding layer 340, a redistribution circuit structure 350, a bonding layer 360, and a plurality of conductive terminals 370 (see the semiconductor package SP1 of FIG. 19). However, the disclosure is not limited thereto. In addition to or alternatively, the redistribution circuit structure 330 and/or redistribution circuit structure 350 may be omitted. The semiconductor element 300 may include a substrate 310, a plurality of through vias 320, a bonding layer 340, a redistribution circuit structure 350, a bonding layer 360, and a plurality of conductive terminals 370. Alternatively, the semiconductor element 300 may include a substrate 310, a plurality of through vias 320, a bonding layer 340, a bonding layer 360, and a plurality of conductive terminals 370. Alternatively, the semiconductor element 300 may include a substrate 310, a plurality of through vias 320, a redistribution circuit structure 330, a bonding layer 340, a bonding layer 360, and a plurality of conductive terminals 370. In addition to or alternatively, the bonding layer 340 and/or bonding layer 360 may be omitted. In addition to or alternatively, the conductive terminals 370 may be omitted. The semiconductor element 300 may be referred to as an interconnect substrate or structure, or interconnection substrate or structure.

In some embodiments, the substrate 310 is a wafer, such as a bulk semiconductor substrate, a silicon-on-insulator (SOI) substrate, a multi-layered semiconductor substrate, or the like. The semiconductor material of the substrate 310 may be silicon, germanium; a compound semiconductor including silicon carbide, gallium arsenic, gallium phosphide, indium phosphide, indium arsenide, and/or indium antimonide; an alloy semiconductor including silicon germanium (SiGe), GaAsP, AlInAs, AlGaAs, GaInAs, GaInP, and/or GaInAsP; or combinations thereof. The alloy SiGe may be formed over a silicon substrate. The SiGe substrate may be strained. In an alternative embodiment, other substrates, such as multi-layered or gradient substrates, may also be used. The substrate 310 may be doped or undoped. The substrate 310 may include a wide variety of devices (not shown) (also referred to as semiconductor devices) formed therein. The devices may include active devices, passive devices, or a combination thereof. The devices may include integrated circuits devices. The devices may include transistors, capacitors, resistors, diodes, photodiodes, fuse devices, jumpers, inductors, or other similar devices. The functions of the devices may include memory, processors, sensors, amplifiers, power distribution, input/output circuitry, or the like. The devices each may be referred to as a semiconductor component. For example, the active devices and/or passive devices (such as transistors, capacitors, resistors, diodes, photodiodes, fuse devices, jumpers, inductors, and the like) are formed in and/or on a surface S310f of the substrate 310. In some embodiments, the surface S310f is referred to as an active surface (or a front side) of the substrate 310. Alternatively, the substrate 310 may be substantially free of active devices and passive devices, and merely provide routing functions.

In some embodiments, through vias 320 are formed in the substrate 310 to extend from the surface S310f of the substrate 310 to a position inside the substrate 310 and is not exposed by a surface S310b of the substrate 310, where the surface S310b is opposite to the surface S310f along the stacking direction Z. The through vias 320 may be formed by forming recesses in the substrate 310 (by, for example, etching, milling, laser techniques, a combination thereof, and/or the like) and depositing a conductive material in the recesses. The conductive material may be formed by an electro-chemical plating process, chemical vapor deposition (CVD), atomic layer deposition (ALD), physical vapor deposition (PVD), a combination thereof, and/or the like. Examples of conductive materials are copper, tungsten, aluminum, silver, gold, a combination thereof, and/or the like. An optional thin dielectric layer (not shown) may be formed in the recesses, such as by using an oxidation technique, to separate the substrate 310 and the through vias 320. A thin barrier layer (not shown) may be conformally formed in the recesses, such as by CVD, ALD, PVD, thermal oxidation, a combination thereof, and/or the like, to separate the substrate 310 and the optional thin dielectric layer. The thin barrier layer may comprise a nitride or an oxynitride, such as titanium nitride, titanium oxynitride, tantalum nitride, tantalum oxynitride, tungsten nitride, a combination thereof, and/or the like. Excess conductive material, the thin barrier layer and the optional thin dielectric layer are removed from the surface S310f of the substrate 310 by, for example, chemical mechanical polishing (CMP) process. Thus, the through vias 320 may comprise a conductive material, a thin barrier layer between the conductive material and the substrate 310 and an optional dielectric layer between the thin barrier layer and the substrate 310. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, a redistribution circuit structure 330 is formed on the surface S310f of the substrate 310, and is electrically connected to the substrate 310. In certain embodiments, the redistribution circuit structure 330 includes a dielectric structure 332 and one or more metallization layers 334 arranged therein for providing routing functionality. For example, the dielectric structure 332 includes one or more dielectric layers, such that the dielectric layers and the metallization layer 334 are sequentially formed, and one metallization layer 334 is sandwiched between two dielectric layers. As shown in FIG. 1, portions of an illustrated top surface of a topmost layer of the metallization layers 334 may be respectively exposed by a topmost portion (e.g., a topmost dielectric layer) of the dielectric structure 332, and portions of an illustrated bottom surface of a bottommost layer of the metallization layers 334 may be respectively exposed by a bottommost portion (e.g., a bottommost dielectric layer) of the dielectric structure 332; however, the disclosure is not limited thereto. For example, the illustrated top surface (not label) of the topmost layer of the metallization layers 334 is substantially level with an illustrated top surface (not label) of the topmost dielectric layer of the dielectric structure 332. In such case, the illustrated top surface (not label) of the topmost layer of the metallization layers 334 may be substantially coplanar to the illustrated top surface (not label) of the topmost dielectric layer of the dielectric structure 332. On the other hand, for example, the illustrated bottom surface (not label) of the bottommost layer of the metallization layers 334 is substantially level with an illustrated bottom surface (not label) of the bottommost dielectric layer of the dielectric structure 332. In such case, the illustrated bottom surface (not label) of the bottommost layer of the metallization layers 334 may be substantially coplanar to the illustrated bottom surface (not label) of the bottommost dielectric layer of the dielectric structure 332.

The material of the dielectric structure 332 may include silicon oxide, silicon nitride, silicon oxy-nitride, or any other suitable dielectric materials, and may be formed by deposition or the like. The metallization layers 334 may be or include patterned copper layers or other suitable patterned metal layers, and may be formed by electroplating or deposition. However, the disclosure is not limited thereto. Alternatively, the metallization layers 334 may be formed by single or dual-damascene method. The numbers of the metallization layers and the dielectric layers included in the redistribution circuit structure 330 is not limited thereto, and may be designated and selected based on the demand and design layout.

The through vias 320 may be connected to the portions of the illustrated bottom surface of the bottommost layer of the metallization layers 334 respectively exposed by the bottommost dielectric layer of the dielectric structure 332, as shown in FIG. 1. In other words, the redistribution circuit structure 330 is electrically connected to the through vias 320. The redistribution circuit structure 330 may further be electrically connected to the active and/or passive devices embedded in the substrate 310 or formed on the surface S310f of the substrate 310 (if any) by direct contacts therebetween. In some embodiments, through the redistribution circuit structure 330, the through vias 320 are electrically coupled to the substrate 310 and/or the active and/or passive devices embedded in the substrate 310 or formed on the surface S310f of the substrate 310 (if any).

In some embodiments, the bonding layer 340 is formed on the redistribution circuit structure 330, where the redistribution circuit structure 330 is disposed between the bonding layer 340 and the substrate 310. For example, the bonding layer 340 includes a dielectric layer 342 and a plurality of connecting pads 344 disposed in the dielectric layer 342, where the connecting pads 344 are electrically coupled to the redistribution circuit structure 330 by directly contacting the metallization layers 334. For example, as shown in FIG. 1, the connecting pads 344 penetrate through and are laterally covered by the dielectric layer 342, where illustrated top surfaces (not label) of the connecting pads 344 are accessibly revealed by the dielectric layer 342. The bonding layer 340 including the dielectric layer 342 and the connecting pads 344 may be referred to as a bonding structure, a connecting layer or a connecting structure of the semiconductor element 300. In some embodiments, illustrated top surfaces of the connecting pads 344 are substantially level with an illustrated top surface (not label) of the dielectric layer 342. In other words, the illustrated top surfaces of the connecting pads 344 are substantially coplanar with the illustrated top surface of the dielectric layer 342. In the disclosure, the illustrated top surfaces of the connecting pads 344 and the illustrated top surface of the dielectric layer 342 may together constitute a front side or an outermost surface of the semiconductor element 300 for connecting to another component (e.g., the semiconductor dies 100), sometimes.

An optional seed layer (not shown) may be formed before forming the connecting pads 344 and after the formation of the dielectric layer 342 so to facilitate the formation of the connecting pads 344. In some embodiments, the bonding layer 340 may be formed by, but not limited to, forming a blanket layer of dielectric material over the redistribution circuit structure 330; patterning the dielectric material blanket layer to form the dielectric layer 342 having a plurality of opening holes (not labeled) penetrating through the dielectric layer 342 and accessibly revealing portions of the illustrated top surface of the exposed topmost layer of the metallization layers 334; optionally forming a blanket layer of seed layer material over the dielectric layer 342, the seed layer material blanket layer extending into the opening holes to line the opening holes and in contact with the exposed portions of the illustrated top surface of the exposed topmost layer of the metallization layers 334; forming a blanket layer of a conductive material over the seed layer material blanket layer and to fill the opening holes; patterning the conductive material blanket layer to form a plurality of connecting pads 344; using the connecting pads 344 as etching mask to pattern the seed layer material blanket layer and form a respective optional seed layer, thereby forming the bonding layer 340. In some embodiments, the optional seed layer is a metal layer, which may be a single layer or a composite layer comprising a plurality of sub-layers formed of different materials. In some embodiments, the optional seed layer comprises a titanium layer and a copper layer over the titanium layer, or two titanium layers and a cupper layer sandwiched between the two titanium layers. The optional seed layer may be formed using, for example, sputtering or the like. Similarly, optional seed layers (not shown) may be adapted to facilitate the formation of the metallization layers 334, if needed. The disclosure is not limited thereto.

Continued on FIG. 1 and FIG. 2, in some embodiments, at least one semiconductor die is disposed over the substrate 310 of the semiconductor element 300 within each region R1. For illustrative purposes and simplicity, only two semiconductor dies 100 are shown in FIG. 1 and only four semiconductor dies 100 are shown in FIG. 2. In some embodiments, each of the semiconductor dies 100 includes a semiconductor substrate 110, an interconnect structure 120 disposed on the semiconductor substrate 110, a passivation layer 130 disposed on the interconnect structure 120, and a plurality of conductive vias 140 penetrating through the passivation layer 130 and disposed on the interconnect structure 120. As shown in FIG. 1, the semiconductor substrate 110 has a frontside surface S110f and a backside surface S110b opposite to the frontside surface S110f, and the interconnect structure 120 is located on the frontside surface S110f of the semiconductor substrate 110, where the interconnect structure 120 is sandwiched between the semiconductor substrate 110 and the passivation layer 130 and sandwiched between the semiconductor substrate 110 and the conductive vias 140, for example.

In some embodiments, the semiconductor substrate 110 is a silicon substrate including active devices (e.g., transistors and/or memories such as N-type metal-oxide semiconductor (NMOS) and/or P-type metal-oxide semiconductor (PMOS) devices, or the like) and/or passive devices (e.g., resistors, capacitors, inductors or the like) formed therein. In some embodiments, such active devices and passive devices are formed in a front-end-of-line (FEOL) process. In an alternative embodiment, the semiconductor substrate 110 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 110 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GalnP, and/or GaInAsP; or combinations thereof. Other substrates, such as multi-layered or gradient substrates, may also be used. For example, the semiconductor substrate 110 has an active surface (e.g., the frontside surface S110f), sometimes called a top side, and a non-active surface (e.g., the backside surface S110b), sometimes called a bottom side.

In some embodiments, the interconnect structure 120 includes one or more inter-dielectric layers 122 and one or more patterned conductive layers 124 stacked alternately. For examples, the inter-dielectric layers 122 are silicon oxide layers, silicon nitride layers, silicon oxy-nitride layers, or dielectric layers formed by other suitable dielectric materials, and are formed by deposition or the like. For examples, the patterned conductive layers 124 are patterned copper layers or other suitable patterned metal layers, and are formed by electroplating or deposition. However, the disclosure is not limited thereto. Alternatively, the patterned conductive layers 124 may be formed by a single or dual-damascene method. The number of the inter-dielectric layers 122 and the number of the patterned conductive layers 124 may be less than or more than what is depicted in FIG. 1, and may be designated and selected based on the demand and/or design layout; the disclosure is not specifically limited thereto. In some embodiments, the interconnect structure 120 is formed in a back-end-of-line (BEOL) process. In certain embodiments, as shown in FIG. 1, the patterned conductive layers 124 are sandwiched between the inter-dielectric layers 122, where a surface of the outermost layer of the patterned conductive layers 124 is at least partially exposed by an outermost layer of the inter-dielectric layers 122 to connect to later formed component(s) for electrical connection (e.g. with the conductive vias 140), and a surface of an innermost layer of the patterned conductive layers 124 is at least partially exposed by an innermost layer of the inter-dielectric layers 122 and electrically connected to the active devices and/or passive devices included in the semiconductor substrate 110.

In some embodiments, as shown in FIG. 1, the passivation layer 130 is formed on the interconnect structure 120, where parts of the interconnect structure 120 is covered by and in contact with the passivation layer 130, and rest of the interconnect structure 120 is accessibly revealed by the passivation layer 130. As shown in FIG. 1, the passivation layer 130 has a substantially planar surface (e.g., an outermost surface S130a), for example. In certain embodiments, the outermost surface S130a of the passivation layer 130 is leveled and may have a high degree of planarity and flatness, which is beneficial for the later-formed layers/elements (e.g., the conductive vias 140). In some embodiments, the passivation layer 130 includes a polyimide (PI) layer, a polybenzoxazole (PBO) layer, a silicon dioxide based (non-organic) layer or other suitable polymer (or organic) layer, and is formed by deposition or the like. The disclosure is not limited thereto. The disclosure does not specifically limit a thickness of the passivation layer 130 as long as the passivation layer 130 can maintain its high degree of planarity and flatness. In the disclosure, the outermost surface S130a of the passivation layer 130 may be referred to as a front (or active) side of the semiconductor die 100.

In some embodiments, the conductive vias 140 are formed on the interconnect structure 120 and over the semiconductor substrate 110, and sidewalls of the conductive vias 140 are wrapped around by the passivation layer 130, as least partially. In some embodiments, as shown in FIG. 1, the conductive vias 140 each penetrate through the passivation layer 130 to physically contact the surface of the outermost layer of the patterned conductive layers 124 exposed by the outermost layer of the inter-dielectric layers 122. Through the interconnect structure 120, the conductive vias 140 are electrically connected to the active devices and/or passive devices included in the semiconductor substrate 110. In some embodiments, the conductive vias 140 in physical contact with the interconnect structure 120 are extended away from the outermost surface S130a of the passivation layer 130. For simplification, only five conductive vias 140 are presented in FIG. 1 in the semiconductor die 100 for illustrative purposes, however it should be noted that more than five conductive vias 140 may be formed; the disclosure is not limited thereto.

In some embodiments, the conductive vias 140 are formed by photolithography, plating, photoresist stripping processes or any other suitable method. The plating process may include an electroplating plating, an electroless plating, or the like. For example, the conductive vias 140 is formed by, but not limited to, forming a mask pattern (not shown) covering the passivation layer 130 with opening holes (not shown) corresponding to the surface of the outermost layer of the patterned conductive layers 124 exposed by the outermost layer of the inter-dielectric layers 122, patterning the passivation layer 130 to form contact openings (not shown) therein for exposing the surface of the outermost layer of the patterned conductive layers 124 exposed by the outermost layer of the inter-dielectric layers 122, forming a metallic material to fill the opening holes formed in the mask pattern and the contact openings formed in the passivation layer 130 to form the conductive vias 140 by electroplating or deposition, and then removing the mask pattern. The passivation layer 130 may be patterned by an etching process, such a dry etching process, a wet etching process, or the combination thereof. The mask pattern may be removed by acceptable ashing process and/or photoresist stripping process, such as using an oxygen plasma or the like. In one embodiment, the material of the conductive vias 140 includes a metal material such as copper or copper alloys, or the like.

In some embodiments, in a vertical projection on the frontside surface S110f of the semiconductor substrate 110 along the (stacking) direction Z of the semiconductor substrate 110, the interconnect structure 120 and the passivation layer 130, the conductive vias 140 may independently be in a circle-shape, an ellipse-shape, a triangle-shape, a rectangle-shape, or the like. The shape of the conductive vias 140 is not limited in the disclosure. The shape and number of the conductive vias 140 may be designated and selected based on the demand and design layout, and may be adjusted by changing the shape and number of the contact openings formed in the passivation layer 130.

Alternatively, the conductive vias 140 may be formed by, but not limited to, forming a first mask pattern (not shown) covering the passivation layer 130 with first opening holes (not shown) corresponding to the surface of the outermost layer of the patterned conductive layers 124 exposed by the outermost layer of the inter-dielectric layers 122, patterning the passivation layer 130 to form the contact openings (not shown) therein for exposing the surface of the outermost layer of the patterned conductive layers 124 exposed by the outermost layer of the inter-dielectric layers 122, removing the first mask pattern, conformally forming a metallic seed layer over the passivation layer 130, forming a second mask pattern (not shown) covering the metallic seed layer with second opening holes (not shown) exposing the contact openings formed in the passivation layer 130, forming a metallic material to fill the second opening holes formed in the second mask pattern and the contact openings formed in the passivation layer 130 by electroplating or deposition, removing the second mask pattern, and then removing the metallic seed layer not covered by the metallic material to form the conductive vias 140.

In some embodiments, the metallic seed layer is referred to as a metal layer, which includes a single layer or a composite layer comprising a plurality of sub-layers formed of different materials. In some embodiments, the metallic seed layer includes titanium, copper, molybdenum, tungsten, titanium nitride, titanium tungsten, combinations thereof, or the like. For example, the metallic seed layer may include a titanium layer and a copper layer over the titanium layer. The metallic seed layer may be formed using, for example, sputtering, PVD or the like.

In some embodiments, the semiconductor dies 100 each further includes a seal ring 150 embedded in the interconnect structure 120 to surround the patterned conductive layers 124 inside the inter-dielectric layers 122. Owing to the seal ring 150, the interconnect structure 120 (e.g., the inter-dielectric layers 122 and the patterned conductive layers 124) is protected from the physical damages and/or the moistures or hydrogen attacks for the environment.

In some embodiments, for each semiconductor die 100, a sidewall of the semiconductor substrate 110, a sidewall of the interconnect structure 120 and a sidewall of the passivation layer 130 are substantially aligned with each other in the direction Z and together constitute a sidewall SW 100 of the semiconductor die 100. For example, illustrated outermost surfaces (e.g., not level) of the conductive vias 140 are protruding away from the outermost surface S130a of the passivation layer 130, as shown in FIG. 1. Alternatively, illustrated outermost surface of the conductive vias 140 may be substantially level with and substantially coplanar to the outermost surface S130a of the passivation layer 130.

It is appreciated that, in some embodiments, the semiconductor dies 100 independently described herein may be referred to as a semiconductor chip or an integrated circuit (IC). In some embodiments, the semiconductor dies 100 independently is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies 100 independently may be or include a digital chip, an analog chip or a mixed signal chip. The semiconductor dies 100 independently may be a chip or an IC of combination-type, such as a WiFi chip simultaneously including both of a RF chip and a digital chip.

In alternative embodiments, each of the semiconductor dies 100 independently includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash, a wide I/O memory (WIO) die, a high bandwidth memory (HBM) die, the like, etc.) with or without a controller. In alternative embodiments, the semiconductor dies 100 independently is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc.; a combination thereof; or the like. In other alternative embodiments, the high-power semiconductor dies 100 independently is an electrical and/or optical input/output (I/O) interface die, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like. The type of the semiconductor dies 100 independently may be selected and designated based on the demand and design requirement, and thus is not specifically limited in the disclosure.

In some embodiments, the types of all of the semiconductor dies 100 are identical. In alternative embodiments, the types of some of the semiconductor dies 100 are different from each other, while the types of some of the semiconductor dies 100 are identical types. In further alternative embodiments, the types of all of the semiconductor dies 100 are different. In some embodiments, the sizes of all of the semiconductor dies 100 are the same. In alterative embodiments, the sizes of some of the semiconductor dies 100 are different from each other, while the sizes of some of the semiconductor dies 100 are the same sizes. In further alternative embodiments, the sizes of all of the semiconductor dies 100 are different. In some embodiments, the shapes of all of the semiconductor dies 100 are identical. In alternative embodiments, the shapes of some of the semiconductor dies 100 are different from each other, while the shapes of some of the semiconductor dies 100 are identical. In further alternative embodiments, the shapes of all of the semiconductor dies 100 are different. The types, sizes and shapes of each of the semiconductor dies 100 are independent from each other, and may be selected and designed based on the demand and design layout, the disclosure is not limited thereto.

As illustrated shown in FIG. 1 and FIG. 2, the semiconductor dies 100 may be bonded to the semiconductor element 300. For example, the semiconductor dies 100 are picked and placed on the semiconductor element 300, and are bonded to the semiconductor element 300 by flip-chip bonding. The semiconductor dies 100 are bonded to the semiconductor element 300 by connecting the conductive vias 140 and some of the connecting pads 344 through a plurality of solder regions 200, for example. In some embodiments, the semiconductor dies 100 are electrically coupled and electrically communicated to each other through the semiconductor element 300 and the solder regions 200. The solder may include lead or be lead-free, and may include Sn—Ag, Sn—Cu, Sn—Ag—Cu, or the like. The solder regions 200 may be referred to as connectors, conductive connectors, conductive elements.

In some embodiments, an underfill 400 at least fills the gaps between the semiconductor dies 100 and the semiconductor element 300 (e.g., the bonding layer 340) and wraps sidewalls of the conductive vias 140 and the solder regions 200, for each region R1. The solder regions 200 and the connecting pads 140 protruding from the passivation layers 130 of the semiconductor dies 100 are covered by (e.g., in physical contact with) the underfill 400. In some embodiments, the underfill 400 filled in the gaps between the semiconductor dies 100 and the redistribution circuit structure 330 within one region R1 is not connected to another underfill 400 filled in the gaps between the semiconductor dies 100 and the redistribution circuit structure 330 within another one region R1, as shown in FIG. 2 in conjunction with FIG. 4. As shown in FIG. 1, the sidewalls SW100 of the semiconductor dies 100 are at least partially covered by of the underfill 400, where the underfill 400 in contact with the sidewalls SW100 of the semiconductor dies 100 at the periphery of the region R1 has a triangle-shape portion. Such triangle-shape portion of the underfill 400 at the sidewalls SW100 near the periphery of the region R1 may be referred to as an underfill fillet. The underfill 400 may be any acceptable material, such as a polymer, epoxy resin, molding underfill, or the like, for example. The underfill 400 may be formed by underfill dispensing, a capillary flow process, or any other suitable method. Owing to the underfill 400, the bonding strength between the semiconductor dies 100 and the semiconductor element 300 is enhanced. For example, the underfill 400 in each region R1 has a first surface S400b in contact with the semiconductor element 300, a second surface S400t opposing to the first surface S400b, and a third surface SW400 extending from (e.g., connecting) the first surface S400b to the second surface S400t. As shown in FIG. 1, the third surface SW400 may stop at the sidewalls SW100 of the semiconductor dies 100 at the periphery of each region R1, and the second surface S400t may be substantially level with the backside surfaces 110b of the semiconductor dies 100.

Referring to FIG. 3 through FIG. 5, in some embodiments, a pre-cutting process is performed on the structure of FIG. 1 along the cutting lines SL1 and SL2, where the underfill 400 is partially removed. For example, in each of the regions R1, the pre-cutting process is at least performed on the underfill 400 to partially remove the underfill 400 disposed on the sidewalls SW100 of the semiconductor dies 100 at the periphery of the respective region R1. That is to say, the triangle-shape portion of the underfill 400 disposed on the sidewalls SW 100 of the semiconductor dies 100 near the periphery of each region R1 may be removed from the sidewalls SW100 of the semiconductor dies 100 at the periphery of the respective region R1, as shown in FIG. 5. The pre-cutting process may include a trimming process performed by direct blade cutting. For example, the pre-cutting process is performed by a mechanical cutting process with a blade 60, where the blade 60 includes a blade body and a plurality of diamond particles distributed over an outer surface of the blade body, and the outer surface of the blade body is configured to be in contact with the object to-be-cut during the pre-cutting process. A lateral size W60 (referred to as a blade width) of the blade 60 (e.g., the blade body) may be approximately from 300 μm to 1000 μm, although other suitable blade width may alternatively be utilized. That is to say, the pre-cutting process may be a contact cutting process. In some embodiments, the pre-cutting process stops at the underfill 400. In other words, the pre-cutting process does not cut through the underfill 400, as shown in FIG. 3 and FIG. 5, for example. Owing to the removal of the underfill fillet (e.g., the triangle-shape portion of the underfill 400), the stress accumulation at such location can be mitigated, thereby the delamination between the underfill (e.g., trimmed underfill 400) and underlying the circuit structure (e.g., semiconductor clement 300) near the periphery of the regions R1 can be suppressed or eliminated. In addition, due to the performing the pre-cutting process, a formation window of the underfill is enlarged. In some embodiments, the pre-cutting process includes a single-cut process. As shown in FIG. 3 and FIG. 5 in conjunction with FIG. 4, a plurality of trenches 54 are formed after the pre-cutting process, where the trenches 54 are confined by two immediately adjacent cutting lines (corresponding to different regions R1). For example, the trenches 54 are in a form of grid. In some embodiments, during the removal of the underfill fillet, the sidewalls SW100 of the semiconductor dies 100 in contact with the underfill fillet to-be removed are also slightly removed, in which the sidewalls SW100 of the semiconductor dies 100 undergoing the removal process may be referred to as patterned sidewalls SW100′ of the semiconductor dies 100, hereinafter. In the disclosure, for illustrative purposes, the patterned sidewalls SW100′ of the semiconductor dies 100 may be denoted as patterned sidewalls SW100A, SW100B, SW100C, or SW100D in the enlarged views of FIG. 6 through FIG. 10 (also in FIG. 12 through FIG. 16) with greater details, and the surface S400 of the underfill 400 may be denoted as a surface S400A or S400B in the enlarged views of FIG. 6 through FIG. 10 (also in FIG. 12 through FIG. 16) with greater details; however, the disclosure is not limited thereto.

In some embodiments, as shown in FIG. 4, in a vertical projection within each region R1, a lateral size D1 (as measured in the direction Y) between two immediately adjacent semiconductor dies 100 may be approximately from 20 μm to 150 μm, although other suitable lateral size may alternatively be utilized. As shown in FIG. 4, in the vertical projection within each region R1, a lateral size D2 (as measured in the direction X) between two immediately adjacent semiconductor dies 100 may be approximately from 20 μm to 150 μm, although other suitable lateral size may alternatively be utilized. On the other hands, as shown in FIG. 4, in a vertical projection on the semiconductor clement 300, a lateral size D3 (as measured in the direction Y) between two immediately adjacent regions R1 may be approximately from 1500 μm to 3000 μm, although other suitable lateral size may alternatively be utilized. As shown in FIG. 4, in the vertical projection on the semiconductor clement 300, a lateral size D4 (as measured in the direction X) between two immediately adjacent regions R1 may be approximately from 1500 μm to 3000 μm, although other suitable lateral size may alternatively be utilized. For example, in the pre-cutting process, portions of the semiconductor dies 100 are also removed along the removal of the underfill fillet, as the blade 60 may be overlapped with the semiconductor dies 100 along the cutting line SL1 and/or SL2. During the pre-cutting process, the patterned conductive layers 124 of the interconnect structure 120 are still protected by the seal ring 150. As shown in FIG. 5, for example, after the pre-cutting process, the underfill 400 in each region R1 has the first surface S400b in contact with the semiconductor element 300, the second surface S400t opposing to the first surface S400b and substantially coplanar to the backside surfaces S110 of the semiconductor dies 100, a surface S400 opposing to the first surface S400b and laterally extended to (e.g., engaged with) the patterned sidewalls of the semiconductor dies 100, the third surface SW400 continuously extending from (e.g., connecting) the first surface S400b to the surface S400, a vertically extended surface (not shown) connecting to the second surface S400t and being substantially aligned with the patterned sidewalls of the semiconductor dies 100, and a laterally extended surface (not shown) connecting to the vertically extended surface and the third surface SW400 and being substantially aligned with the surface S400, where the third surface SW400 connects the laterally extended surface and the first surface S400b. In some embodiments, a distance between the first surface S400b and the second surface S400t is greater than a distance between the first surface S400b and the surface S400, in the direction Z. In some embodiments, the vertically extended surface is sandwiched between the patterned sidewalls of two adjacent semiconductor dies 100 in the cross-sectional view along the direction Z. In some embodiments, the laterally extended surface is sandwiched between two adjacent parts (or portions) of the surface S400 of the underfill 400 in the top view (e.g., the XY plane).

In some embodiments, during the pre-cutting process in conjunction with FIG. 3 through FIG. 5, a lateral removal length L (measured along the direction X or Y, as shown in FIG. 3) of the semiconductor dies 100 is less than or substantially equal to 1.5% of an overall thickness of the semiconductor dies 100, and a vertical cutting depth D (measured along the direction Z, as shown in FIG. 5) is greater than or substantially equal to 75% of the overall thickness of the semiconductor dies 100. In a non-limiting example, the overall thickness of the semiconductor dies 100 may be 750 μm. The lateral removal length L may be referred to as a die cut length of the semiconductor dies 100, and the vertical cutting depth D may be referred to as a cutting depth of the cutting step performed in the pre-cutting process. Owing to the vertical cutting depth D, the delamination due to the stress accumulation caused by the underfill (e.g., un-trimmed underfill 400) can be suppressed or eliminated.

As shown in FIG. 4 and FIG. 5, the underfill 400 is disposed between the semiconductor dies 100 and the semiconductor element 300 and further extends to surround the edges of the semiconductor dies 100, where a portion P1 of the underfill 400 within the regions R1 and not undergoing the pre-cutting process has the surface S400t, a portion P2 of the underfill 400 outside the regions R1 and undergoing the pre-cutting process has the surface S400, and a portion P3 of the underfill 400 is disposed between the semiconductor dies 100 and the semiconductor element 300. For example, the portion P2 connects and encloses (e.g., continuously surrounds) the portion P1, and the portion P3 connects to the portions P1 and P2. The first portion P1 may be in a grid form or a mesh form. On the other hand, the second potion P2 may be in form of a continuous frame. For each region R1, the portion P1 may be referred to as a branch portion or an inner extending portion of the underfill 400, the portion P2 may be referred to as an outer extending portion, an extending portion, an extension portion, a peripherical portion or an edge portion of the underfill 400, and the portion P3 may be referred to as a body portion or a central portion of the underfill 400. As shown in FIG. 4, the portions P1, P2 and P3 of the underfill 400 are an integral piece, for example. The portion Pl and the portion P2 in each region R1 is not overlapped with the semiconductor dies 100, in some embodiments. For example, the portion P1 is disposed between the semiconductor dies 100 in each region R1, and the portion P2 is disposed along the outer edges of the semiconductor dies 100 in each region R1. In some embodiments, along the direction Z, a maximum height H1 of the portion P1 is greater than a maximum height H2 of the portion P2.

For a non-limiting example, as shown in FIG. 5 and FIG. 6, the pre-cutting process is performed along the cutting lines SL1 and SL2, such that a plurality of trenches 54 (as denoted by dash-box in FIG. 5 in conjunction with FIG. 4) are formed by removing parts of the semiconductor dies 100 and parts of the underfill 400 for each region R1. After the formation of the trenches 54, the semiconductor dies 100 disposed at the periphery of each region R1 (undergoing the pre-cutting process) respectively have a patterned sidewall SW100A including a surface S1 and a surface S2 connecting to the surface S1, where the underfill 400 has the surface S400A opposing to the first surface S400b and connecting to the third surface SW400, the surface S400A includes a surface S6, and the surface S6 props against the surfaces S2 and S130a, as shown in FIG. 5 and FIG. 6, for example. In some embodiments, the surface S1 is a planar surface, such as a substantially vertical planar surface. In some embodiments, the surface S2 is a non-planar surface, such as a curved surface with a radius of curvature approximately ranging from 0.5 μm to 5.0 μm. In some embodiments, the surface S6 is a planar surface, such as a substantially horizontal planar surface. As shown in FIG. 6, the surface S130a of the semiconductor die 100 (e.g., the passivation layer) may be physically connected to the surface S2 of the sidewall SW100A and in contact with (e.g., covered by) the underfill 400, where the surface S2 may be physically connected to and continuously extended between the surface S1 and the surface S130a, and the surface S1 may be physically connected to and continuously extended between the surface S2 and the backside surface S110b. For example, a portion of the semiconductor die 100 having the surface S1 of the sidewall SW100A has a first lateral size and a portion of the semiconductor die 100 having the surface S2 of the sidewall SW100A has a second lateral size, where the first lateral size is substantially constant, and the second lateral size is tapered from the surface S130a towards the backside surface S110b. As shown in FIG. 6, the surface S2 may be continuously extended between the surface S1 and the surface S6. In some embodiments, the surface S6 is substantially level with the surface S130a. In other words, the surface S6 may be substantially coplanar to the surface S130a, as shown in FIG. 6.

For a non-limiting example, as shown in FIG. 5 and FIG. 7, the pre-cutting process is performed along the cutting lines SL1 and SL2, such that a plurality of trenches 54 (as denoted by dash-box in FIG. 5 in conjunction with FIG. 4) are formed by removing parts of the semiconductor dies 100 and parts of the underfill 400 for each region R1. After the formation of the trenches 54, the semiconductor dies 100 disposed at the periphery of each region R1 (undergoing the pre-cutting process) respectively have a patterned sidewall SW100B including a surface S1, a surface S2 connecting to the surface S1, a surface S3 connecting to the surface S2 and a surface S4 connecting to the surface S3, where the underfill 400 has the surface S400A opposing to the first surface S400b and connecting to the third surface SW400, the surface S400A includes a surface S6, and the surface S6 props against the surface S3 and the surface S4, as shown in FIG. 5 and FIG. 7, for example. In some embodiments, the surface S1 is a planar surface, such as a substantially vertical planar surface. In some embodiments, the surface S2 is a non-planar surface, such as a curved surface with a radius of curvature approximately ranging from 0.5 μm to 5.0 μm. In some embodiments, the surface S3 is a planar surface, such as a substantially horizontal planar surface. In some embodiments, the surface S4 is a planar surface, such as a substantially vertical planar surface. In some embodiments, the surface S6 is a planar surface, such as a substantially horizontal planar surface. As shown in FIG. 7, the surface S130a of the semiconductor die 100 (e.g., the passivation layer) may be physically connected to the surface S4 of the sidewall SW100B and in contact with (e.g., covered by) the underfill 400, where the surface S4 may be physically connected to and continuously extended between the surface S130a and the surface S3 and in contact with (e.g., covered by) the underfill 400, the surface S3 may be physically connected to and continuously extended between the surface S2 and the surface S4, the surface S2 may be physically connected to and continuously extended between the surface S1 and the surface S3, and the surface S1 may be physically connected to and continuously extended between the backside surface S110b and the surface S2. For example, a portion of the semiconductor die 100 having the surface S1 of the sidewall SW100B has a first lateral size, a portion of the semiconductor die 100 having the surface S2 of the sidewall SW100B has a second lateral size, and a portion of the semiconductor die 100 having the surface S4 of the sidewall SW 100B has a third lateral size, where the first lateral size is substantially constant, the second lateral size is tapered from the surface S3 towards the backside surface S110b, and the third lateral size is substantially constant and is greater than the first lateral size of the first portion and the second lateral size of the second portion. As shown in FIG. 7, the surface S1 may be indented from the surface S4, and the surface S2 and surface 3 may be continuously extended between the surface S1 and the surface S6. In some embodiments, the surface S3 is substantially level with the surface S6. In other words, the surface S3 may be substantially coplanar to the surface S6, as shown in FIG. 7. In some embodiments, a portion of the semiconductor die 100 extending from the surface S2 toward the surface S4 with a length correspond to the surface S3 may be referred to as an extending portion P4 of the semiconductor die 100. As shown in FIG. 7, the portion P4 is in a plate form extending along the X-Y plane.

For a non-limiting example, as shown in FIG. 5 and FIG. 8, the pre-cutting process is performed along the cutting lines SL1 and SL2, such that a plurality of trenches 54 (as denoted by dash-box in FIG. 5 in conjunction with FIG. 4) are formed by removing parts of the semiconductor dies 100 and parts of the underfill 400 for each region R1. After the formation of the trenches 54, the semiconductor dies 100 disposed at the periphery of each region R1 (undergoing the pre-cutting process) respectively have a patterned sidewall SW100A including a surface S1 and a surface S2 connecting to the surface S1, where the underfill 400 has the surface S400B opposing to the first surface S400b and connecting to the third surface SW400, the surface S400B includes a surface S5 and a surface S6 connecting to the surface S5, and the surface S5 props against the surfaces S2 and S130a, as shown in FIG. 5 and FIG. 8, for example. In some embodiments, the surface S1 is a planar surface, such as a substantially vertical planar surface. In some embodiments, the surface S2 is a non-planar surface, such as a curved surface with a radius of curvature approximately ranging from 0.5 μm to 5.0 μm. In some embodiments, the surface S5 is a non-planar surface, such as a curved surface with a radius of curvature approximately ranging from 0.5 μm to 5.0 μm. The curvature of radius for the surface S2 may substantially identical to the curvature of radius for the surface S5. In some embodiments, the surface S6 is a planar surface, such as a substantially horizontal planar surface. As shown in FIG. 8, the surface S130a of the semiconductor die 100 (e.g., the passivation layer) may be physically connected to the surface S2 of the sidewall SW100A and in contact with (e.g., covered by) the underfill 400, where the surface S2 may be physically connected to and continuously extended between the surface S1 and the surface S130a, and the surface S1 may be physically connected to and continuously extended between the surface S2 and the backside surface S110b. On the other hand, the surface S6 may be physically connected to and continuously extended between the surface S5 and the third surface SW400, in FIG. 5 and FIG. 8. For example, a portion of the semiconductor die 100 having the surface S1 of the sidewall SW 100A has a first lateral size and a portion of the semiconductor die 100 having the surface S2 of the sidewall SW100A has a second lateral size, where the first lateral size is substantially constant, and the second lateral size is tapered from the surface S130a towards the backside surface S110b. As shown in FIG. 8, the surface S2 may be continuously extended between the surface S1 and the surface S5, and the surface S5 may be continuously extended between the surface S2 and the surface S6. In some embodiments, the surface S6, which is free from the semiconductor dies 100, is below the surface S130a. In other words, there is a height difference between the surface S130a and the surface S6.

For a non-limiting example, as shown in FIG. 5 and FIG. 9, the pre-cutting process is performed along the cutting lines SL1 and SL2, such that a plurality of trenches 54 (as denoted by dash-box in FIG. 5 in conjunction with FIG. 4) are formed by removing parts of the semiconductor dies 100 and parts of the underfill 400 for each region R1. After the formation of the trenches 54, the semiconductor dies 100 disposed at the periphery of each region R1 (undergoing the pre-cutting process) respectively have a patterned sidewall SW100C including a surface S1, where the underfill 400 has the surface S400B opposing to the first surface S400b and connecting to the third surface SW400, the surface S400B includes a surface S5 and a surface S6 connecting to the surface S5, and the surface S5 props against the surfaces S1 and S130a, as shown in FIG. 5 and FIG. 9, for example. In some embodiments, the surface S1 is a planar surface, such as a substantially vertical planar surface. In some embodiments, the surface S5 is a non-planar surface, such as a curved surface with a radius of curvature approximately ranging from 0.5 μm to 5.0 μm. In some embodiments, the surface S6 is a planar surface, such as a horizontal planar surface. As shown in FIG. 9, the surface S130a of the semiconductor die 100 (e.g., the passivation layer) may be physically connected to the surface S1 of the sidewall SW100C and in contact with (e.g., covered by) the underfill 400, where the surface S1 may be physically connected to and continuously extended between the surface S130a and the backside surface S110b. On the other hand, the surface S6 may be physically connected to and continuously extended between the surface S5 and the third surface SW400, in FIG. 5 and FIG. 9. For example, a portion of the semiconductor die 100 having the surface S1 of the sidewall SW100C has a first lateral size, where the first lateral size is substantially constant. As shown in FIG. 9, the surface S5 may be continuously extended between the surface S1 and the surface S6. In some embodiments, the surface S6, which is free from the semiconductor dies 100, is below the surface S130a. In other words, there is a height difference between the surface S130a and the surface S6.

For a non-limiting example, as shown in FIG. 5 and FIG. 10, the pre-cutting process is performed along the cutting lines SL1 and SL2, such that a plurality of trenches 54 (as denoted by dash-box in FIG. 5 in conjunction with FIG. 4) are formed by removing parts of the semiconductor dies 100 and parts of the underfill 400 for each region R1. After the formation of the trenches 54, the semiconductor dies 100 disposed at the periphery of each region R1 (undergoing the pre-cutting process) respectively have a patterned sidewall SW100D including a surface S1, a surface S2 connecting the surface S1 and a surface S4 connecting to the surface S2, where the underfill 400 has the surface S400B opposing to the first surface S400b and connecting to the third surface SW400, the surface S400B includes a surface S5 and a surface S6 connecting to the surface S5, and the surface S5 props against the surfaces S1 and S130a, as shown in FIG. 5 and FIG. 10, for example. In some embodiments, the surface S1 is a planar surface, such as a substantially vertical planar surface. In some embodiments, the surface S2 is a non-planar surface, such as a curved surface with a radius of curvature approximately ranging from 0.5 μm to 5.0 μm. In some embodiments, the surface S4 is a planar surface, such as a substantially vertical planar surface. In some embodiments, the surface S5 is a non-planar surface, such as a curved surface with a radius of curvature approximately ranging from 0.5 μm to 5.0 μm. In some embodiments, the surface S6 is a planar surface, such as a horizontal planar surface. As shown in FIG. 10, the surface S130a of the semiconductor die 100 (e.g., the passivation layer) may be physically connected to the surface S4 of the sidewall SW 100D and in contact with (e.g., covered by) the underfill 400, where the surface S2 may be physically connected to and continuously extended between the surface S1 and the surface S4, and the surface S4 may be physically connected to and continuously extended between the surface S2 and the surface S130a. On the other hand, the surface S6 may be physically connected to and continuously extended between the surface S5 and the third surface SW400, in FIG. 5 and FIG. 10. For example, a portion of the semiconductor die 100 having the surface S1 of the sidewall SW100D has a first lateral size, where the first lateral size is substantially constant. As shown in FIG. 10, the surface S5 may be continuously extended between the surface S1 and the surface S6. In some embodiments, the surface S6, which is free from the semiconductor dies 100, is below the surface S130a. In other words, there is a height difference between the surface S130a and the surface S6.

Referring to FIG. 11, in some embodiments, an insulating encapsulation 500 is formed over the semiconductor element 300 to cover the semiconductor dies 100, the underfill 400 and the semiconductor element 300 exposed therefrom. For example, the insulating encapsulation 500 at least fills up the gaps between the semiconductor dies 100 disposed in and between the regions R1 and between the underfill 400 disposed between the adjacent regions R1. In some embodiments, the semiconductor dies 100 and the underfill 400 are surrounded and covered by the insulating encapsulation 500. As shown in FIG. 11, the backside surfaces S110b (e.g., the non-active surface) of the semiconductor dies 100 may not be accessibly revealed by a surface S500 of the insulating encapsulation 500. However, the disclosure is not limited thereto. In the case, the semiconductor dies 100 and the underfill 400 are embedded in and encapsulated by the insulating encapsulation 500, and the semiconductor element 300 is covered by the insulating encapsulation 500.

In some embodiments, the insulating encapsulation 500 is a molding compound formed by a molding process. In some embodiments, the insulating encapsulation 500 include polymers (such as epoxy resins, phenolic resins, silicon-containing resins, or other suitable resins), dielectric materials, or other suitable materials. In an alternative embodiment, the insulating encapsulation 500 may include an acceptable insulating encapsulation material. The insulating encapsulation 500 may further include inorganic filler or inorganic compound (e.g., silica, clay, and so on) which can be added therein to optimize coefficient of thermal expansion (CTE) of the insulating encapsulation 500, the disclosure is not limited thereto. The insulating encapsulation 500 may be referred to as an encapsulant, a dielectric encapsulation, or an encapsulation. For example, the insulating encapsulation 500 is formed by, but not limited to, over-molding the semiconductor dies 100 by an insulating encapsulation material, and patterning the insulating encapsulation material to form the insulating encapsulation 500. The insulating encapsulation material may be patterned by a planarizing process until obtaining a substantially flat and planar surface therefrom (e.g., S500). Owing to the insulating encapsulation 500, the bonding strength between the semiconductor dies 100, the underfill 400 and the semiconductor element 300 is further enhanced, and the semiconductor dies 100 are protected from the damages caused by the external contacts.

The planarizing process is performed by mechanical grinding, CMP, etching or combinations thereof, for example. The etching may include dry etching, wet etching, or a combination thereof. After the planarizing process, a cleaning process may be optionally performed to clean and remove the residue generated from the planarizing process. However, the disclosure is not limited thereto, and the planarizing process may be performed through any other suitable method.

With the formation of the insulating encapsulation 500, the trenches 54 are filled by the insulating encapsulation 500, for example. In some embodiment, the insulating encapsulation 500 covers the backside surface S110b and the patterned sidewalls SW100′ (e.g., the surfaces SW100A-SW100D depicted in FIG. 12 through FIG. 16, which has been respectively discussed in FIG. 6 through FIG. 10) of the semiconductor dies 100 exposed by the underfill 400), the third surface SW400 and the surface S400 (e.g., the surfaces S400A-S00B depicted in FIG. 12 through FIG. 16, which has been respectively discussed in FIG. 6 through FIG. 10) of the underfill 400, and the semiconductor element 300 exposed by the semiconductor dies 100 and the underfill 400.

Referring to FIG. 17, in some embodiments, a planarizing process is performed to expose the through vias 320 from the substrate 310. Before performing the planarizing process, the structure of FIG. 11 may be overturned (e.g., flipped upside down along the stacking direction Z) and placed onto a holding device 50. For example, as shown in FIG. 17, the surface S500 of the insulating encapsulation 500 is attached to the holding device 50, so that the structure is secured in place during the planarizing process. For example, the holding device 50 may be an adhesive tape, a carrier film or a suction pad. The disclosure is not limited thereto. In some embodiments, a portion of the substrate 310 is removed by the planarizing process to expose the through vias 320, such that the surface S310b of the substrate 310 and surfaces S320 of the through vias 320 are substantially level with each other. In other words, the surface S310b of the substrate 310 and the surfaces S320 of the through vias 320 are substantially coplanar to each other. As shown in FIG. 17, the surfaces S320 of the through vias 320 are accessibly revealed by the surface S310b of the substrate 310. In the disclosure, since the through vias 320 extend through the substrate 310, the through vias 320 may be referred to as through-substrate-vias, through-semiconductor-vias or through-silicon-vias (TSVs) 320 when the substrate 310 is a silicon substrate.

In some embodiments, the planarizing process may include a grinding process, a CMP process, an etching process, the like, or combinations thereof; however, the disclosure is not limited thereto. After planarizing, a cleaning process may be optionally performed, for example to clean and remove the residue generated from the planarizing process. However, the disclosure is not limited thereto, and the planarizing process may be performed through any other suitable method.

Referring to FIG. 18, in some embodiments, the redistribution circuit structure 350 and the bonding layer 360 are sequentially formed on the substrate 310. For example, the redistribution circuit structure 350 is formed on the surface S310b of the substrate 310, and is electrically connected to the substrate 310. In certain embodiments, the redistribution circuit structure 350 includes a dielectric structure 352 and one or more metallization layers 354 arranged therein for providing routing functionality. For example, the dielectric structure 352 includes one or more dielectric layers, such that the dielectric layers and the metallization layer 354 are sequentially formed, and one metallization layer 354 is sandwiched between two dielectric layers. As shown in FIG. 18, portions of an illustrated top surface of a topmost layer of the metallization layers 354 may be respectively exposed by a topmost portion (e.g., a topmost dielectric layer) of the dielectric structure 352, and portions of an illustrated bottom surface of a bottommost layer of the metallization layers 354 may be respectively exposed by a bottommost portion (e.g., a bottommost dielectric layer) of the dielectric structure 352; however, the disclosure is not limited thereto. For example, the illustrated top surface (not label) of the topmost layer of the metallization layers 354 is substantially level with an illustrated top surface (not label) of the topmost dielectric layer of the dielectric structure 352. In such case, the illustrated top surface (not label) of the topmost layer of the metallization layers 354 may be substantially coplanar to the illustrated top surface (not label) of the topmost dielectric layer of the dielectric structure 352. On the other hand, for example, the illustrated bottom surface (not label) of the bottommost layer of the metallization layers 354 is substantially level with an illustrated bottom surface (not label) of the bottommost dielectric layer of the dielectric structure 352. In such case, the illustrated bottom surface (not label) of the bottommost layer of the metallization layers 354 may be substantially coplanar to the illustrated bottom surface (not label) of the bottommost dielectric layer of the dielectric structure 352. The formation and material of the redistribution circuit structure 350 (including the dielectric structure 352 and the metallization layers 354) are substantially identical to or similar to the formation and material of the redistribution circuit structure 330 (including the dielectric structure 332 and the metallization layers 334) previously described in FIG. 1, and thus are not repeated herein for brevity.

The through vias 320 may be connected to the portions of the illustrated bottom surface of the bottommost layer of the metallization layers 354 respectively exposed by the bottommost dielectric layer of the dielectric structure 352, as shown in FIG. 18. In other words, the redistribution circuit structure 350 is electrically connected to the through vias 320. The redistribution circuit structure 350 is electrically coupled to the redistribution circuit structure 330 through the through vias 320, in some embodiments. The redistribution circuit structure 350 is electrically coupled to the active and/or passive devices embedded in the substrate 310 or formed on the surface S310f of the substrate 310 (if any) through the through vias 320 and the redistribution circuit structure 330, in some embodiments. The redistribution circuit structure 350 is electrically coupled to the bonding layer 340 through the through vias 320 and the redistribution circuit structure 330, in some embodiments. The redistribution circuit structure 350 is electrically coupled to the semiconductor dies 100 through the through vias 320, the redistribution circuit structure 330, the bonding layer 340 and the solder regions 200, in some embodiments.

In some embodiments, the bonding layer 360 is formed on the redistribution circuit structure 350, where the redistribution circuit structure 350 is disposed between the bonding layer 360 and the substrate 310. For example, the bonding layer 360 includes a dielectric layer 362 and a plurality of connecting pads 364 disposed in the dielectric layer 362, where the connecting pads 364 are electrically coupled to the redistribution circuit structure 350 by directly contacting the metallization layers 354. For example, as shown in FIG. 18, the connecting pads 364 penetrate through and are laterally covered by the dielectric layer 362, where illustrated top surfaces (not label) of the connecting pads 364 are accessibly revealed by the dielectric layer 362. The bonding layer 360 including the dielectric layer 362 and the connecting pads 364 may be referred to as a bonding structure, a connecting layer or a connecting structure of the semiconductor element 300. In some embodiments, illustrated top surfaces of the connecting pads 364 are substantially level with an illustrated top surface (not label) of the dielectric layer 362. In other words, the illustrated top surfaces of the connecting pads 364 are substantially coplanar with the illustrated top surface of the dielectric layer 362. In the disclosure, the illustrated top surfaces of the connecting pads 364 and the illustrated top surface of the dielectric layer 362 may together constitute a back side or an outermost surface of the semiconductor element 300 for connecting to another component (e.g., the semiconductor dies 100), sometimes.

Continued on FIG. 18, in some embodiments, the conductive terminals 370 are formed over the bonding layer 360, where the bonding layer 360 is disposed between the redistribution circuit structure 350 and the conductive terminals 370. The conductive terminals 370 includes micro-bumps, metal pillars, controlled collapse chip connection (C4) bumps (for example, which may have, but not limited to, a size of about 80 μm), a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like, in some embodiments. The conductive terminals 370 may be referred to as connectors, conductive connectors, conductive elements of the semiconductor element 300 for external connections. In some embodiments, at least some of the conductive terminals 370 are electrically coupled to the semiconductor dies 100 through the bonding layer 360, the redistribution circuit structure 350, the through vias 320, the redistribution circuit structure 330, the bonding layer 340 and the solder regions 200. In some embodiments, at least some of the conductive terminals 370 are electrically coupled to the active and/or passive devices embedded in the substrate 310 or formed on the surface S310f of the substrate 310 (if any) through the bonding layer 360, the redistribution circuit structure 350, the through vias 320, and the redistribution circuit structure 330.

Referring to FIG. 19 and FIG. 20, in some embodiments, a dicing (or singulation) process is performed to cut through the insulating encapsulation 500 and the semiconductor element 300 so to form a plurality of separate and individual semiconductor packages SP1 having a chip-on-wafer (CoW) structure. The semiconductor packages SP1 may be referred to as CoW packages. The dicing (or singulation) process may be or include a wafer dicing process including mechanical blade sawing or laser cutting. The conductive terminals 370 may be referred to as conductive connectors or input/output (I/O) terminals of each semiconductor package SP1. It is appreciated that FIG. 20 is a schematic plane view before dicing, wherein the dicing process is performed along cutting lines SL3.

Prior to the dicing process, the structure of FIG. 18 may be released from the holding device 50 and transferred onto another holding device (not shown) for securing the structure of FIG. 18 during the dicing (or singulation) process, where the conductive terminals 370 may be held by the another holding device. In some embodiments, prior to releasing the conductive terminals 370 from the another holding device, the dicing (or singulation) process is performed. For example, the another holding device may be an adhesive tape, a carrier film or a suction pad.

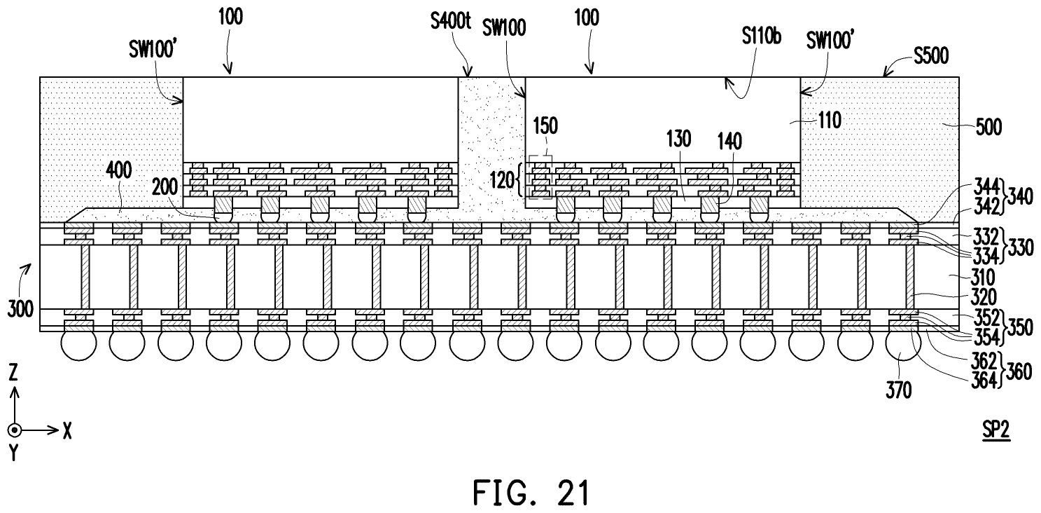

FIG. 21 is a schematic cross-sectional view showing a semiconductor package (e.g., SP2) in accordance with some alternative embodiments of the disclosure. The semiconductor package SP2 of FIG. 21 is similar to the semiconductor package SP1 of FIG. 19, a difference is that, in the semiconductor package SP2 of FIG. 21, the semiconductor dies 100 are exposed by the insulating encapsulation 500. The elements similar to or substantially the same as the elements described previously will use the same reference numbers, and certain details or descriptions (e.g., the materials, formation processes, positioning configurations, etc.) of the same elements would not be repeated herein.

Referring to FIG. 21, in some embodiments, the backside surface S110b (e.g., the non-active surface) of the semiconductor dies 100 are accessibly revealed by the surface S500 of the insulating encapsulation 500. As shown in the semiconductor package SP2 of FIG. 21, the backside surface S110b (e.g., the non-active surface) of the semiconductor dies 100 may be substantially level with the surface S500 of the insulating encapsulation 500. In such cases, the backside surface S110b (e.g., the non-active surface) of the semiconductor dies 100 may be substantially coplanar to the surface S500 of the insulating encapsulation 500. That is, the semiconductor dies 100 are laterally encapsulated by the insulating encapsulation 500. In such case, during the planarizing process, the semiconductor dies 100 independently may also be planarized.

The semiconductor packages SP1, SP2 or the modifications thereof may be further mounted onto another external/additional electronical component, for example, mounted onto a circuit structure, such as a mother board, a package substrate, a printed circuit board (PCB), a printed wiring board, and/or other carrier that is capable of carrying integrated circuits. For a non-limiting example, the semiconductor packages SP1, SP2 or the modifications thereof may be or may be part of an integrated Fan-Out (InFO) package, an InFO package having a Package-on-Package (POP) structure, a chip-on-wafer-on-substrate (CoWoS) package, a flip chip package of an InFO package, or the like. The disclosure is not limited thereto.

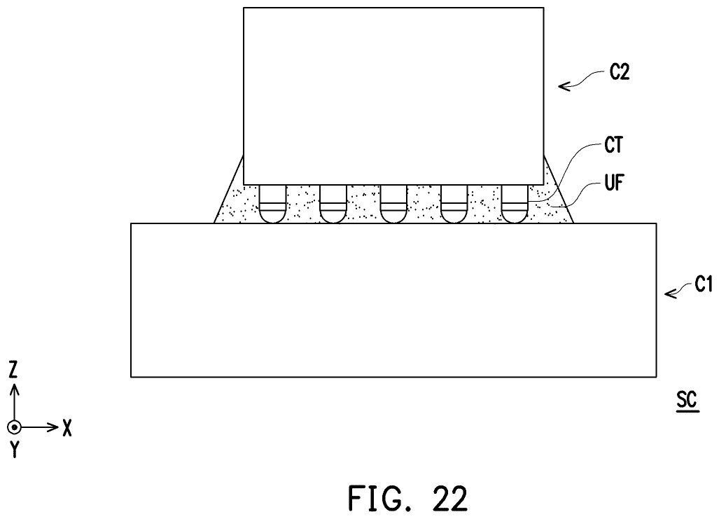

FIG. 22 is a schematic cross-sectional view of an application of a semiconductor package in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 22, in some embodiments, a component assembly SC including a first component C1 and a second component C2 disposed over the first component C1 is provided. The first component C1 may be or may include a circuit structure, such as a mother board, a package substrate, another PCB, a printed wiring board, an interposer, and/or other carrier that is capable of carrying integrated circuits. In some embodiments, the second component C2 mounted on the first component C1 is similar to one of the semiconductor packages SP1, SP2 or the modifications thereof. In a non-limiting example, one or more semiconductor package (e.g., one or multiple semiconductor packages SP1, SP2 and/or the modifications thereof) may be electrically coupled to the first component C1 through a plurality of terminals CT. The terminals CT may be the conductive terminals 370 as previously described.

In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill may be formed by underfill dispensing, a capillary flow process, or any other suitable method. Owing to the underfill UF, a bonding strength between the first component C1 and the second component C2 is enhanced.

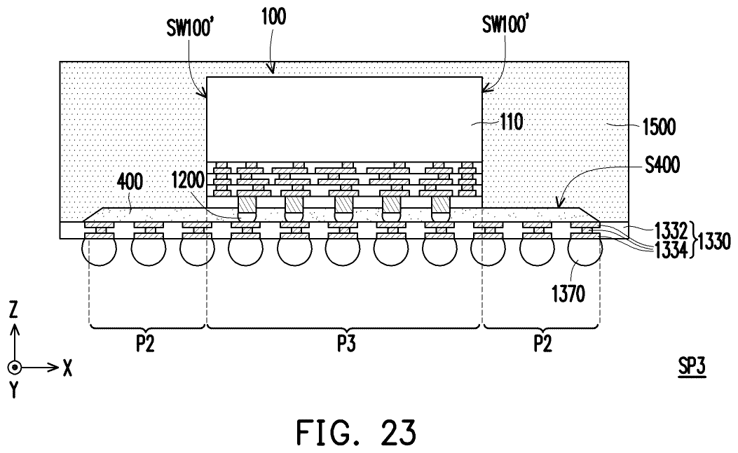

The disclosure is not limited thereto; alternatively, a semiconductor package of the disclosure may be in form of InFO package including a single semiconductor die (e.g., 100) surrounded by a trimmed underfill (e.g., 400 as previously described in FIG. 3 through FIG. 5 in conjunction with FIG. 6 through FIG. 10). In such alternative embodiments, the sidewall of the single semiconductor die (e.g., 100) may be also slightly removed to form a patterned sidewall, where the positioning configuration between the patterned sidewall of the single semiconductor die and the trimmed underfill inside the InFO package may refer to FIG. 6 through FIG. 10. Thereby, the delamination between the trimmed underfill and an underlying structure (e.g., an interconnect substrate or structure, or interconnection substrate or structure; such as a carrier, a semiconductor substrate or a redistribution circuit structure included in the InFO package) can be suppressed or eliminated. In addition, owing to trimming the underfill, the formation window of the underfill is enlarged. The manufacture of such semiconductor package is compatible to the current and/or advanced manufacturing processes. For example, as shown in FIG. 23, a semiconductor package SP3, which is referred to as an InFO package, includes a redistribution circuit structure 1330 (including one or more metallization layers 1334 and a dielectric structure 1332), a semiconductor die 100 disposed over and electrically coupled to the redistribution circuit structure 1330 through solder regions 1200, an underfill 400 disposed between the semiconductor die 100 and the redistribution circuit structure 1330, an insulating encapsulation 1500 encapsulating the semiconductor die 100 and the underfill 400, and a plurality of conductive terminals 1370 disposed over and electrically coupled to the redistribution circuit structure 1330. As shown in FIG. 23, the underfill 400 may cover the solder regions 1200 and the conductive vias 140 protruding out the passivation layer 130, and the insulating encapsulation 1500 may cover the semiconductor die 100, the underfill 400 and the redistribution circuit structure 1330 exposed from the semiconductor die 100 and the underfill 400. In some embodiments, the backside surface S110b of the semiconductor die 100 is covered by the insulating encapsulation 1500. Alternatively, the backside surface S110b of the semiconductor die 100 is accessibly revealed by the insulating encapsulation 1500.

For example, the underfill 400 is disposed between the semiconductor die 100 and the redistribution circuit structure 1330 and further extends to surround the edge of the semiconductor die 100, where the underfill 400 includes a portion P3 interposed between the semiconductor die 100 and the redistribution circuit structure 1330 and a portion P2 outside the semiconductor die 100 and undergoing the pre-cutting process with a surface S400. The portion P2 may be in form of a continuous frame. Sometimes, the portion P2 may be referred to as an extending portion, a peripherical portion, an extension portion or an edge portion of the underfill 400, where the portion P3 may be referred to as a body portion or a central portion of the underfill 400. The portion P3 and the portion P2 of the underfill 400 may be connected to each other. As shown in FIG. 23, the portion P3 and the portion P2 of the underfill 400 are an integral piece, for example. In a non-limiting example, along the direction Z, a maximum height of the portion P3 is greater than a maximum height of the portion P2 (also in conjunction with FIG. 8/FIG. 14 and FIG. 9/FIG. 15). In a non-limiting example, along the direction Z, a maximum height of the portion P3 is less than a maximum height of the portion P2 (also in conjunction with FIG. 7/FIG. 13 and FIG. 10/FIG. 16). In a non-limiting example, along the direction Z, a maximum height of the portion P3 is substantially equal to a maximum height of the portion P2 (also in conjunction with FIG. 6/FIG. 12). The redistribution circuit structure 1330 may be referred to as an interconnect substrate or structure, or interconnection substrate or structure.

The semiconductor package SP3 may be formed by, but not limited to, forming the redistribution circuit structure 1330 over a temporary carrier (not shown); bonding the semiconductor die 100 through the solder regions 1200 onto the redistribution circuit structure 1330 by flip-chip bonding; forming an underfill material (not shown) over the redistribution circuit structure 1330 to fill the gap between the redistribution circuit structure 1330 and the redistribution die 100, where the underfill material surrounds the semiconductor die 100; forming a pre-cutting process to form the underfill 400 have the portion P3 between the redistribution circuit structure 1330 and the redistribution die 100 and the portion P2 surrounding the semiconductor die 100; encapsulating the underfill 400 and the semiconductor die 100 in the insulating encapsulation 1500, the insulating encapsulation 1500 further covers the redistribution circuit structure exposed by the underfill 400 and the semiconductor die 100; debonding the temporary carrier from the redistribution circuit structure 1330; and disposing the conductive terminals 1370 over the redistribution circuit structure 1330, the conductive terminals 1370 are electrically coupled to the semiconductor dies 100 through the redistribution circuit structure 1330 and the solder regions 1200. The details of the semiconductor die 100 and the underfill 400 have been previously discussed in FIG. 1 through FIG. 17, and thus are not repeated herein for simplicity. In addition, the formation, materials and details of the solder regions 1200, the redistribution circuit structure 1330 (including the metallization layers 1334 and the dielectric structure 1332), the conductive terminals 1370 and the insulating encapsulation 1500 may be similar or substantially identical to the formation, materials and details of the solder regions 200, the redistribution circuit structure 330 (including the metallization layers 334 and the dielectric structure 332), the conductive terminals 370 and the insulating encapsulation 500 discussed in FIG. 1 through FIG. 17, and thus are not repeated herein. In some embodiments, after forming the conductive terminals 1370, a dicing (singulation) process is performed to separate a wafer-form of multiple semiconductor packages SP3 (physically connected to one another) to individual and discrete semiconductor packages SP3.

Similarly, the semiconductor package SP3 and/or the modifications thereof may be further mounted onto another external/additional electronical component, for example, mounted onto a circuit structure, such as a mother board, a package substrate, a printed circuit board (PCB), an interposer, a printed wiring board, and/or other carrier that is capable of carrying integrated circuits. For a non-limiting example, the semiconductor package SP3 and/or the modifications thereof may be or may be part of an InFO package, an InFO package having a PoP structure, a chip-on wafer (CoW) package, a CoWoS package, a flip chip package of an InFO package, or the like. The disclosure is not limited thereto.

In accordance with some embodiments, a semiconductor package includes an interconnect substrate, a semiconductor die, and an underfill. The semiconductor die is disposed over the interconnect substrate and has a first top surface extends along a first direction. The underfill includes a body portion and an extending portion. The body portion is disposed between the interconnect substrate and the semiconductor die. The extending portion connects to the body portion, where the extending portion is next to the semiconductor die and has a second top surface extends along the first direction.

In accordance with some embodiments, a semiconductor package includes an interconnect substrate, a die, an underfill, and an insulating encapsulation. The die is disposed over the interconnect substrate and electrically coupled thereto, where the die has an upper sidewall and a lower sidewall connected to the upper sidewall. The underfill laterally surrounds the die. The insulating encapsulation encapsulates the die and the underfill. The upper sidewall of the die extends along a first direction, the lower sidewall of the die and the insulating encapsulation have an interface therebetween, and the interface extends along a second direction different from the first direction.

In accordance with some embodiments, a method of manufacturing a semiconductor package includes the following steps: bonding a semiconductor die to an interconnection substrate through connectors; dispensing an underfill material to laterally surround the connector, wherein the underfill material comprises a central portion and an extension portion laterally surrounding the central portion; and removing a portion of the extension portion to expose a sidewall of the semiconductor die.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor package, comprising:
an interconnect substrate;
a semiconductor die, disposed over the interconnect substrate and has a first top surface extends along a first direction; and
an underfill, comprising:
a body portion, disposed between the interconnect substrate and the semiconductor die; and
an extending portion, connecting to the body portion, wherein the extending portion is next to the semiconductor die and has a second top surface extends along the first direction.

2. The semiconductor package of claim 1, wherein a first height of the body portion is greater than a second height of the extending portion along a stacking direction of the interconnect substrate and the semiconductor die.

3. The semiconductor package of claim 1, wherein a first height of the body portion is substantially equal to a second height of the extending portion along a stacking direction of the interconnect substrate and the semiconductor die.

4. The semiconductor package of claim 1, wherein a first height of the body portion is less than a second height of the extending portion along a stacking direction of the interconnect substrate and the semiconductor die.

5. The semiconductor package of claim 1, wherein a portion of the semiconductor die is laterally covered by the underfill, and a surface of the portion of the semiconductor die is substantially level with a surface of the extending portion of the underfill.

6. The semiconductor package of claim 1, wherein the extending portion has a bottom surface and the second top surface opposing to the bottom surface, the bottom surface is in contact with the interconnect substrate, and
wherein the second top surface comprises a planar surface, and the planar surface engages the semiconductor die.

7. The semiconductor package of claim 1, wherein the extending portion has a bottom surface and the second top surface opposing to the bottom surface, the bottom surface is in contact with the interconnect substrate, and
wherein the second top surface comprises a planar surface extending along the first direction and a curved surface connecting to the planar surface, and the curved surface continuously extends from the planar surface to the semiconductor die.

8. A semiconductor package, comprising:
an interconnect substrate;
a die, disposed over the interconnect substrate and electrically coupled thereto, wherein the die has an upper sidewall and a lower sidewall connected to the upper sidewall;
an underfill, laterally surrounding the die; and
an insulating encapsulation, encapsulating the die and the underfill,
wherein the upper sidewall of the die extends along a first direction, the lower sidewall of the die and the insulating encapsulation have an interface therebetween, and the interface extends along a second direction different from the first direction.

9. The semiconductor package of claim 8, wherein the lower sidewall comprises a curved surface.

10. The semiconductor package of claim 8, wherein the curved surface has a radius of curvature approximately ranging from 0.5 μm to 5.0 μm.

11. The semiconductor package of claim 8, wherein the lower sidewall comprises a curved surface extending along the second direction, a vertical surface extending along the first direction and a lateral surface extending along a direction substantially perpendicular to the first direction, wherein the lateral surface continuously extending between the curved surface and the vertical surface.

12. The semiconductor package of claim 8, wherein the lower sidewall comprises a curved surface extending along the second direction and a vertical surface extending along the first direction, wherein the curved surface continuously extending between the vertical surface and the upper sidewall.

13. The semiconductor package of claim 8, wherein the underfill comprises a planar upper surface.

14. The semiconductor package of claim 8, wherein the underfill comprises a planar upper surface and a curved surface connecting the planar upper surface, and the curved surface is in contact with the die.

15. The semiconductor package of claim 14, wherein the curved surface has a radius of curvature approximately ranging from 0.5 μm to 5.0 μm.

16. A method of manufacturing a semiconductor package, comprising:
bonding a semiconductor die to an interconnection substrate through connectors;
dispensing an underfill material to laterally surround the connector, wherein the underfill material comprises a central portion and an extension portion laterally surrounding the central portion; and
removing a portion of the extension portion to expose a sidewall of the semiconductor die.

17. The method of claim 16, wherein removing the portion of the extension portion of the underfill material comprises performing a pre-cutting process to remove the portion of the extension portion and a portion of the semiconductor die in contact with the portion of the extension portion.

18. The method of claim 16, wherein removing the portion of the extension portion of the underfill material comprises performing a trimming process, and
after the trimming process, the extension portion comprises a planar surface engaging to the sidewall of the semiconductor.

19. The method of claim 16, wherein removing the portion of the extension portion of the underfill material comprises performing a trimming process, and
after the trimming process, the extension portion comprises a planar surface and a curved surface connecting to the planar surface, wherein the curved surface extended from the planar surface to the sidewall of the semiconductor.

20. The method of claim 16, further comprising:
encapsulating the semiconductor die and the underfill material in an insulating encapsulation.
